(19) United States
(12) Patent Application Publication
(10) Pub. No.: US 2013/0263925 A1
(43) Pub. Date: Oct. 10, 2013

(54) Hole Carrier Layer For Organic Photovoltaic Device

(71) Applicants: Russell Gaudiana, Lyndeborough, NH (US); David P. Waller, Lexington, MA (US); Michael Lee, Billerica, MA (US); Edward Lindholm, Brookline, MA (US); Claire Lepont, Brookline, MA (US)

(72) Inventors: Russell Gaudiana, Lyndeborough, NH (US); David P. Waller, Lexington, MA (US); Michael Lee, Billerica, MA (US); Edward Lindholm, Brookline, MA (US); Claire Lepont, Brookline, MA (US)

(73) Assignee: Merck Patent Gmbh, Darmstadt (DE)

(21) Appl. No.: 13/842,380

(22) Filed: Mar. 15, 2013

Related U.S. Application Data
(60) Provisional application No. 61/620,540, filed on Apr. 5, 2012.
(60) Provisional application No. 61/771,415, filed on Mar. 1, 2013.

(51) Int. Cl. H01L 51/00

(52) U.S. Cl. CPC H01L 51/0043; H01L 51/0007
USPC 136/263; 438/82

(57) ABSTRACT

The present invention relates to a photovoltaic cell that comprises a first electrode, a second electrode, a photoactive layer between the first electrode and the second electrode, and a hole carrier layer between the first electrode and the photoactive layer. In one embodiment, the hole carrier layer comprises an oxidizing agent and a hole carrier polymer.

### CROSS-REFERENCE TO RELATED APPLICATIONS

This application claims benefit under 35 U.S.C. §119 of U.S. Provisional Application Ser. No. 61/620,540, filed Apr. 5, 2012, and U.S. Provisional Application Ser. No. 61/771,415, filed Mar. 1, 2013, the contents of both of which are hereby incorporated by reference.

### STATEMENT REGARDING FEDERALLY SPONSORED RESEARCH OR DEVELOPMENT

This invention was made with government support under 70NAN7H7048 awarded by the National Institutes of Standards and Testing. The government has certain rights in the invention.

### BACKGROUND OF THE INVENTION

1. Field of the Invention

The present invention relates to a photovoltaic cell that comprises a first electrode, a second electrode, a photoactive layer between the first electrode and the second electrode, and a hole carrier layer between the first electrode and the photoactive layer, with the hole carrier layer comprising an oxidizing agent and a hole carrier polymer.

2. Description of the Background

Photovoltaic cells are commonly used to transfer energy in form of light into electricity. A typical photovoltaic cell comprises a first electrode, a second electrode and a photoactive layer between the first and second electrode. Generally, one of the electrodes allows light passing through to the photoactive layer. This transparent electrode may for example be made of a film of semiconductive material (such as for example indium tin oxide).

Frequently, photovoltaic cells have a hole carrier layer that comprises acidic hole carrier materials, such as for example poly(3,4-ethylenedioxythiophene) doped with polystyrenesulfonate (“PEDOT:PSS”), so as to provide a photovoltaic cell with sufficiently high conversion efficiency.

However, such acidic hole carrier materials are corrosive and tend to reduce the life time of the photovoltaic cells. There is a need to provide photovoltaic cells that allow the transformation of light into electrical energy, and have an improved life span.

### SUMMARY OF THE INVENTION

The present application discloses an article comprising a first electrode, a second electrode, a photoactive layer between the first electrode and the second electrode, and a hole carrier layer between the first electrode and the photoactive layer, the hole carrier layer comprising an oxidizing agent and a hole carrier polymer, wherein the oxidizing agent is selected from the group consisting of an article comprising a first electrode, a second electrode, a photoactive layer between the first electrode and the second electrode, and a hole carrier layer between the first electrode and the photoactive layer, the hole carrier layer comprising an oxidizing agent and a hole carrier polymer, wherein the oxidizing agent is selected from the group consisting of

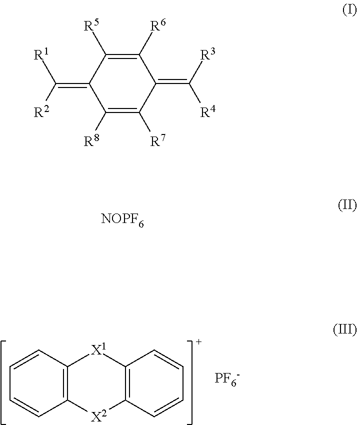

and blends thereof, wherein R¹ to R⁸ are independently of each other selected from the group consisting of hydrogen, fluorine, chlorine, bromine, iodine, NO₂, NH₂, COOH, and CN, with the provision that at least two of R¹ to R⁸ are different from hydrogen, and wherein X¹ and X² are independently of each other selected from the group consisting of O, S, Se, NR⁹ with R⁹ being selected from the group consisting of alkyl having from 1 to 10 carbon atoms, phenyl and phenyl substituted with alkyl having from 1 to 10 carbon atoms, or one of R⁵ to R⁸ may be -Sp-Pol selected from the group consisting of the following (I-Pol-A), (I-Pol-B), (I-Pol-C)

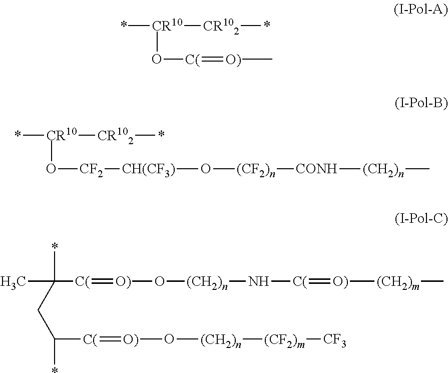

and blends thereof, with R¹⁰ being hydrogen or fluorine, preferably fluorine; each n and m being independently of the other a number between 0 and 10, preferably between 0 and 5, most preferably 1 or 2; and “*” indicating the bonds to other monomeric units of the polymer, wherein the article is a photovoltaic cell. In certain preferred embodiments, at least two of R⁵-R⁸ are selected from the group consisting of hydrogen, fluorine, chlorine, NO₂, COOH, and CN.

In certain preferred embodiments, the electron donor material comprises a polymer having the repeat unit of formula IV, below.

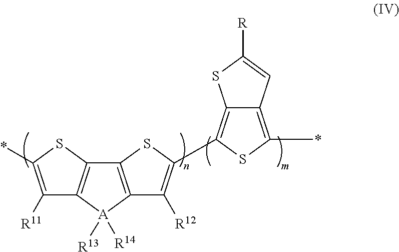

where R, R¹¹, R¹², R¹³, and R¹⁴ are independently of each other selected from the group consisting of hydrogen, or hydrocarbyl with 1 to 40 C atoms that is optionally substituted and optionally comprises one or more hetero atoms, and A is C or Si. In certain embodiments, R, R¹¹, R¹², R¹³, and R¹⁴ are independently of each other selected from the group consisting of hydrogen, substituted or unsubstituted C₁-C₂₄ alkyl, C₁-C₂₄ alkyl interrupted by one or more oxygen, aryl, C₁-C₂₄ alkyoxy, or aryloxy.

The present application also provides for a method for manufacturing the present article, wherein the method comprises the steps of
(a) mixing the hole carrier polymer and the oxidizing agent and dissolving them together in a solvent, or dissolving the hole carrier polymer in a first solvent and the oxidizing agent in a second solvent and then mixing the two solutions; and
(b) subsequently coating the resulting solution from step (a) over a layer underneath,
   wherein the first and second solvent may be the same or different, and wherein the article is a photovoltaic cell.

Further, the present application provides for a method for manufacturing the present article, wherein the method comprises the steps of
(a) dissolving the hole carrier polymer in a first solvent to obtain a first solution;
(b) coating the first solution over a layer underneath;
(c) drying the resulting layer of hole carrier polymer;
(d) dissolving the oxidizing agent in a second solvent to obtain a second solution; and
(c) coating the second solution over the layer of hole carrier polymer obtained in step (c);
   wherein the first and second solvent may be the same or different, and wherein the article is a photovoltaic cell.

### BRIEF DESCRIPTION OF THE DRAWINGS

The foregoing and other features and advantages will be apparent from the following more particular description of exemplary embodiments of the disclosure, as illustrated in the accompanying drawings, in which like reference characters refer to the like elements throughout the different views. The drawings are not necessarily to scale, emphasis instead being placed upon illustrating the principles of the disclosure

FIG. 1 is a cross-sectional view of an exemplary embodiment of a photovoltaic cell.

FIG. 2 is a schematic of a system containing multiple photovoltaic cells electrically connected in series.

FIG. 3 is a schematic of a system containing multiple photovoltaic cells electrically connected in parallel.

### DETAILED DESCRIPTION OF PREFERRED EMBODIMENTS

In a general aspect, the present disclosure provides a photovoltaic cell comprising a first electrode, a second electrode, a photoactive layer between the first electrode and the second electrode, and a hole carrier layer between the first electrode and the photoactive layer, the hole carrier layer comprising an oxidizing agent and a hole carrier polymer.

In a further aspect, compositions are disclosed that are useful in forming a hole carrier layer in such photovoltaic cells. In certain embodiments, the disclosed compositions comprise polymers or polymers plus small molecules that form ionomers once they are blended together. In preferred embodiments, components of the compositions form a redox pair. In some embodiments, the compositions are not water sensitive. In preferred embodiments, the compositions are not acidic, and therefore not corrosive to metal and semi-conductor electrodes. In some embodiments, the compositions are colorless. In certain embodiments, the composition the components of the redox pair can be synthesized separately. In certain embodiments, the polymers are solvent soluble.

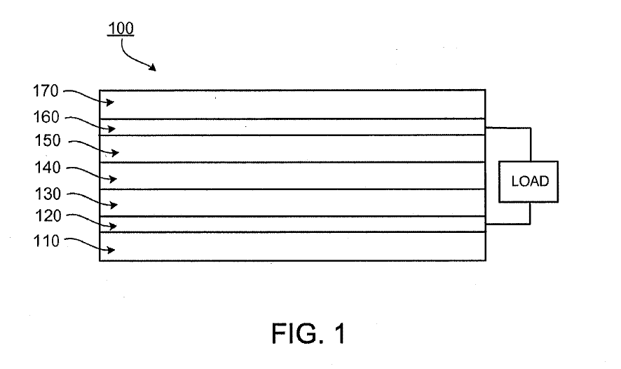

Such an embodiment of a photovoltaic cell, together with some optional layers, is depicted in FIG. 1, which shows a cross-sectional view of an exemplary photovoltaic cell 100 that includes a substrate 110, an electrode 120, an optional hole blocking layer 130, a photoactive layer 140 (e.g., containing an electron acceptor material and an electron donor material), a hole carrier layer 150, an electrode 160, and a substrate 170.

In general, during use, light can impinge on the surface of substrate 110, and passes through substrate 110, electrode 120 and optional hole blocking layer 130. The light then interacts with the photoactive layer 140, causing electrons to be transferred from the electron donor material (e.g., a conjugated polymer) to the electron material (e.g., a substituted fullerene). The electron acceptor material then transmits the electrons through optional hole blocking layer 130 to electrode 120, and the electron donor material transfers holes through hole carrier layer 150 to electrode 160. Electrodes 120 and 160 are in electrical connection via an external load so that electrons pass from electrode 120 though the load to electrode 160.

The present hole carrier layer comprises an oxidizing agent as defined below and a hole carrier polymer as defined below.

### Oxidizing Agents

Suitable oxidizing agents may be selected from the group consisting of

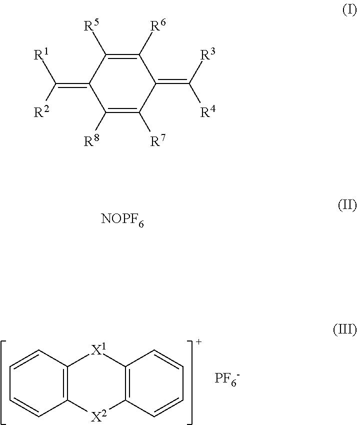

and blends thereof, wherein R¹ to R⁸ are independently of each other selected from the group consisting of hydrogen, fluorine, chlorine, bromine, iodine, NO₂, NH₂, COOH, and CN, with the provision that at least two of R¹ to R⁸ are different from hydrogen, and wherein X¹ and X² are independently of each other selected from the group consisting of O, S, Se, NR⁹ with R⁹ being selected from the group consisting of alkyl having from 1 to 10 carbon atoms, phenyl and phenyl substituted with alkyl having from 1 to 10 carbon atoms. Alternatively, one of R⁵ to R⁸ may be -Sp-Pol as defined below. In certain preferred embodiments, at least two of R⁵-R⁸ are selected from the group consisting of hydrogen, fluorine, chlorine, NO₂, COOH, and CN.

Examples of alkyl having from 1 to 10 carbon atoms are methyl, ethyl, n-propyl, iso-propyl, n-butyl, iso-butyl, tert-butyl, pentyl, hexyl, heptyl, octyl, nonyl and decyl, of which methyl, ethyl, n-propyl, iso-propyl, n-butyl, iso-butyl and tert-butyl are preferred.

Where R¹ to R⁴ are CN, and R⁵ to R⁸ are hydrogen, the compound of formula (I) is tetracyano-quinodimethane (TCNQ). Preferred examples of the compounds of formula (I) are those, wherein at least two, three or four of R¹ to R⁴ and at least two, three or four of R⁵ to R⁸ are different from hydrogen.

Particularly suited substituents R¹ to R⁸ are selected from the group consisting of fluorine, NO₂ and CN; especially fluorine and CN.

Particularly well suited exemplary compounds of formula (I) are the following:

| Compound | R¹ | R² | R³ | R⁴ | R⁵ | R⁶ | R⁷ | R⁸ |
|---|---|---|---|---|---|---|---|---|
| (I-a) | CN | CN | CN | CN | F | F | F | F |
| (I-b) | CN | CN | CN | CN | F | H | F | H |
| (I-c) | CN | CN | CN | CN | F | H | H | F |
| (I-d) | CN | CN | CN | CN | F | F | H | H |
| (I-e) | NO₂ | NO₂ | NO₂ | NO₂ | F | F | F | F |
| (I-f) | NO₂ | NO₂ | NO₂ | NO₂ | F | H | F | H |
| (I-g) | NO₂ | NO₂ | NO₂ | NO₂ | F | H | H | F |
| (I-h) | NO₂ | NO₂ | NO₂ | NO₂ | F | F | H | H |

of which compounds (I-a) and (I-f) are preferred and (I-a) is most preferred.

For the purposes of the present application, compound (I-a) may also be referred to as F4TCNQ, and compound (I-b) as F2TCNQ.

Compound (I) may also be provided in the form of a polymer comprising a monomeric unit wherein one of one of R⁵ to R⁸ of compound (I) may be -Sp-Pol, wherein -Sp-Pol is selected from the group consisting of the following (I-Pol-A), (I-Pol-B), (I-Pol-C)

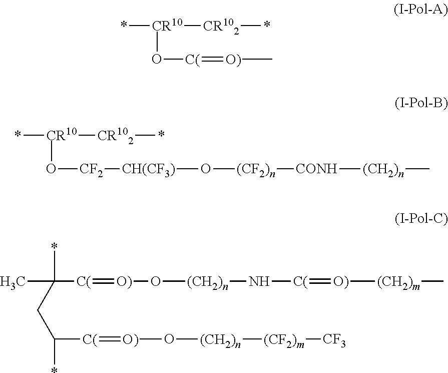

and blends thereof, with R¹⁰ being hydrogen or fluorine, preferably fluorine; each n and m being independently of the other a number between 0 and 10, preferably between 0 and 5, most preferably 1 or 2; and “*” indicating the bonds to other monomeric units of the polymer.

In formula (I-Pol-B) n is preferably 2.

In formula (I-Pol-C) n is preferably 2 and m is preferably 7.

An exemplary compound of formula (I-Pol-B) may for example be produced according to WO 2009/138010 from compound (I), wherein one of R⁵ to R⁸ is substituted with (CH₂)₂—NH₂, and

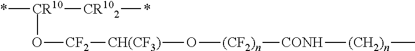

both of which are commercially available.

An exemplary compound of formula (I-Pol-C) may for example be synthesized from

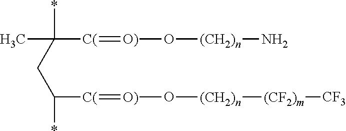

made according to Journal of Applied Polymer Science 114 (2009) 2476, and compound (I), wherein one of R⁵ to R⁸ is substituted with (CH₂)₂—COOH, and which may be synthesized according to Journal of Organic Chemistry 48 (1948) 3852.

The polymers comprising a monomeric unit selected from the group consisting of (I-Pol-A), (I-Pol-B) and (I-Pol-C) may comprise a further monomer of formula

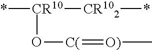

wherein R¹⁰ are independently of each other hydrogen or fluorine, preferably fluorine, and R¹¹ is as defined above. The desired content in oxidizing compound can be adjusted by changing the molar ratio between monomeric units (I-k-A) and (I-k-B).

### Hole Carrier Polymer

Preferably the hole carrier polymer is a polymer capable of donating electrons. Exemplary polymers that are suitable may be selected from the list consisting of polythiophenes, polyanilines, polycarbazoles, polyvinylcarbazoles, polyphenylenes, polyphenylvinylenes, polysilanes, polythienylenevinylenes, polyisothianaphthanenes, and copolymers or blends thereof.

Preferably, the hole carrier polymer comprises one or more monomeric unit selected from the following

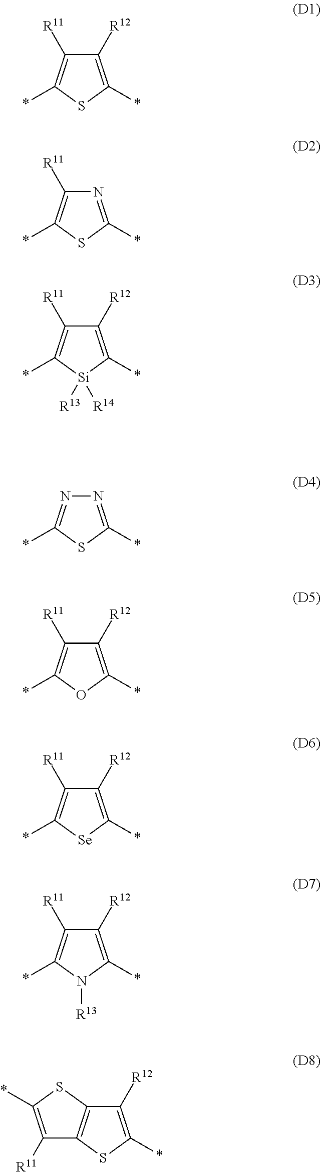

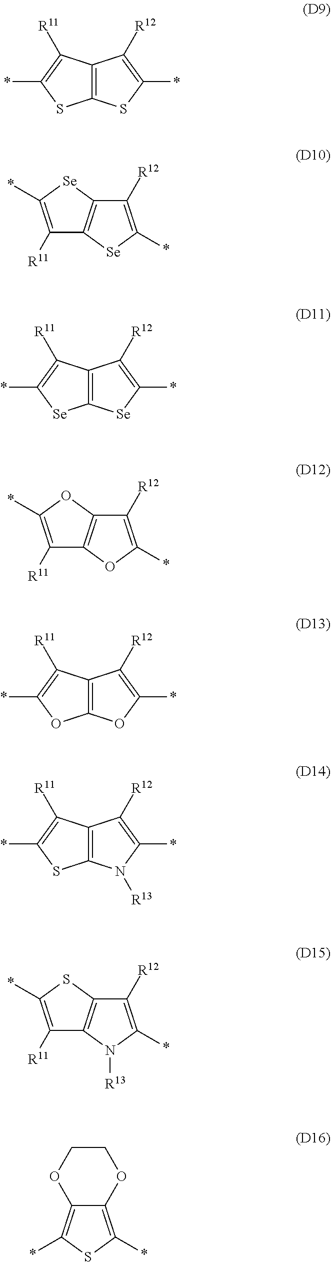

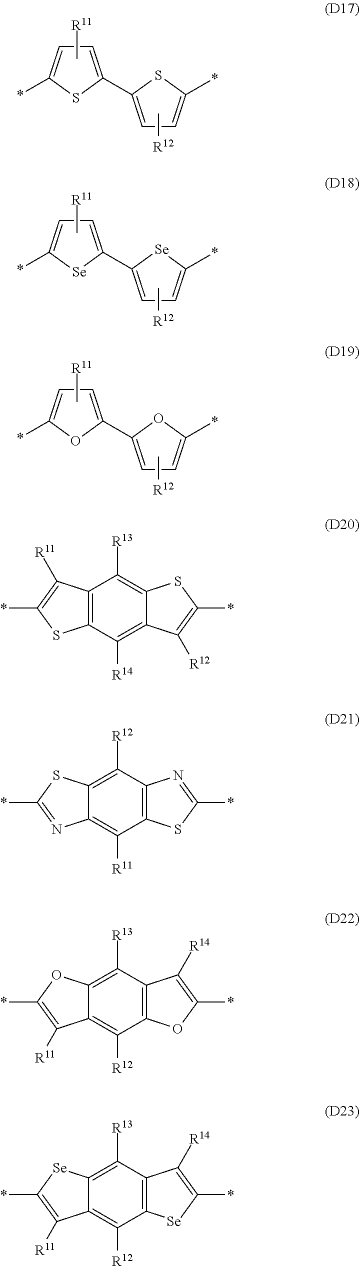

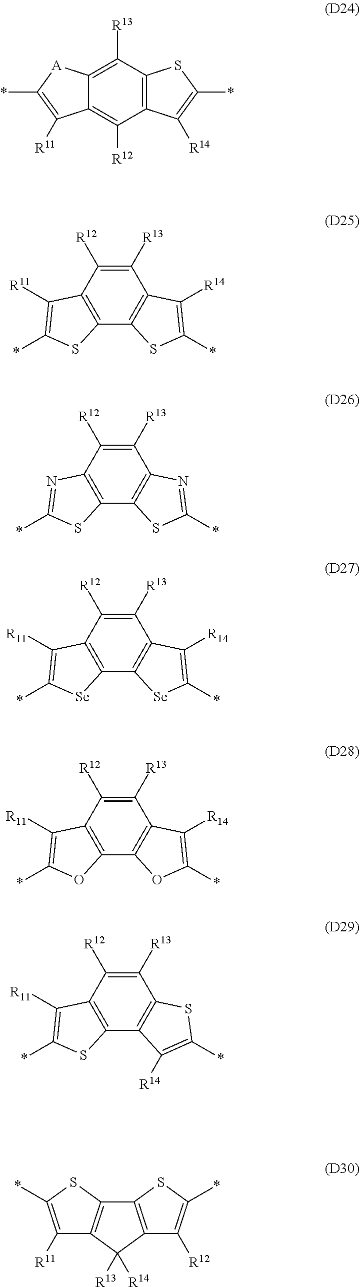

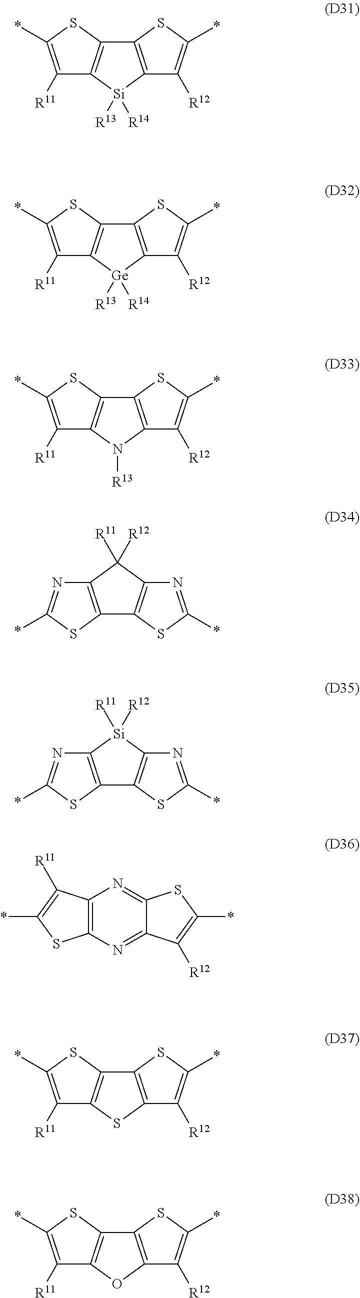

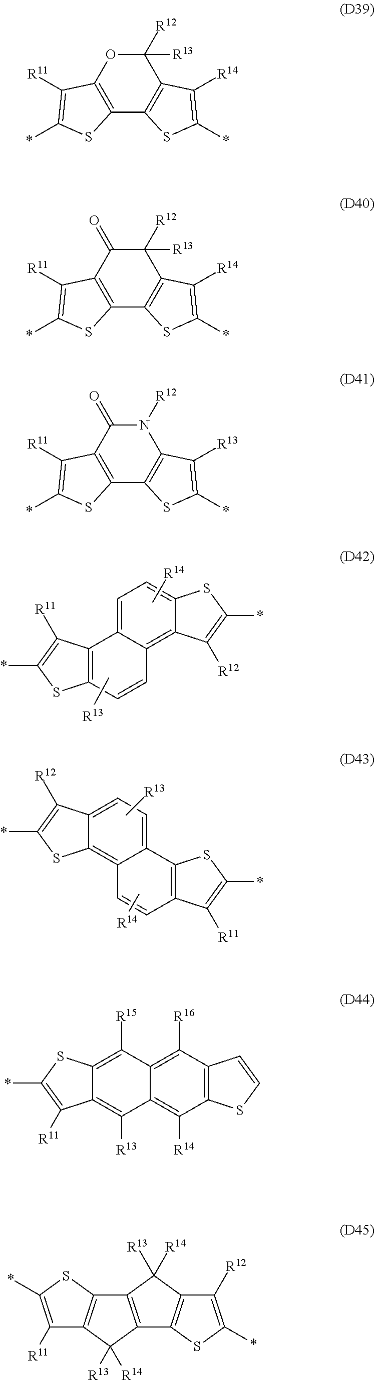

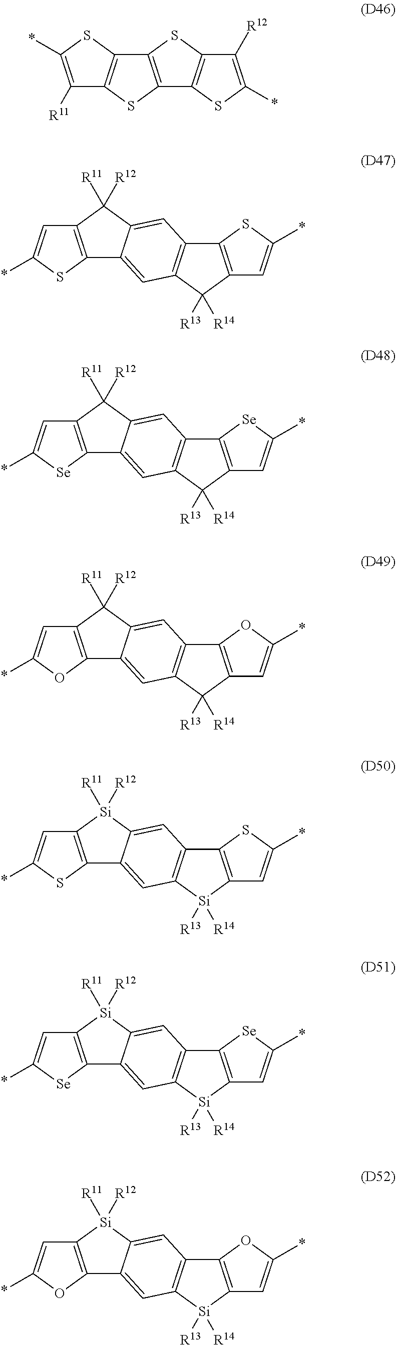

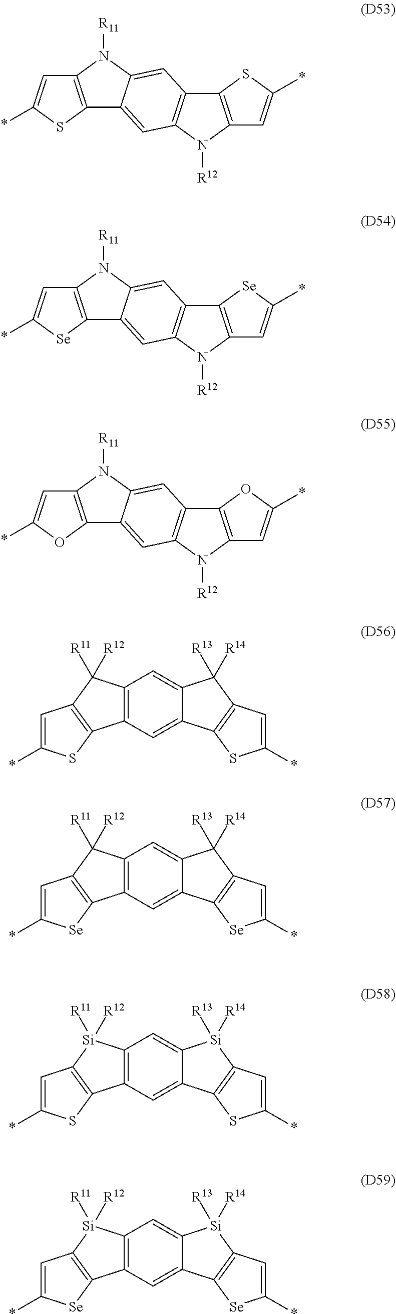

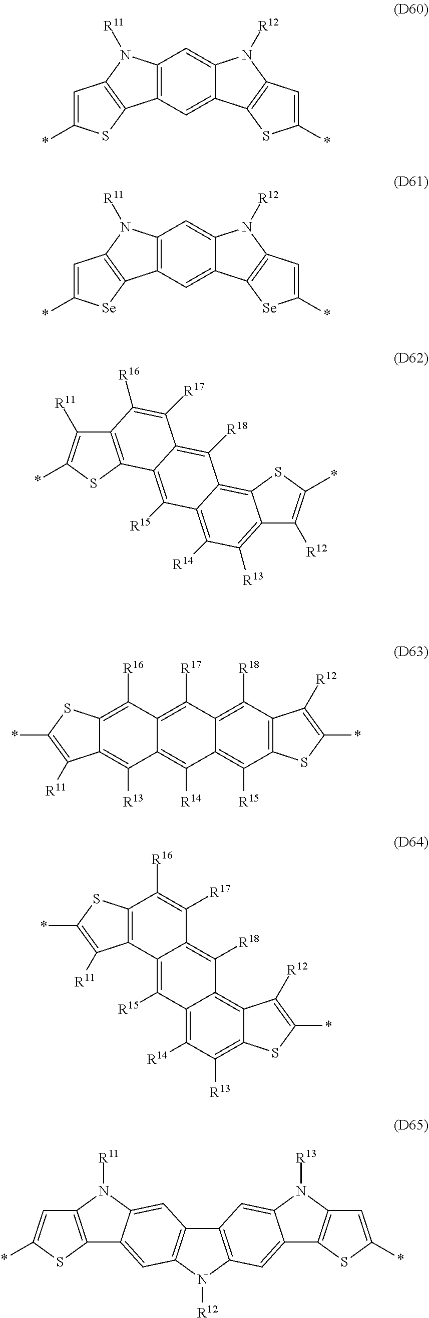

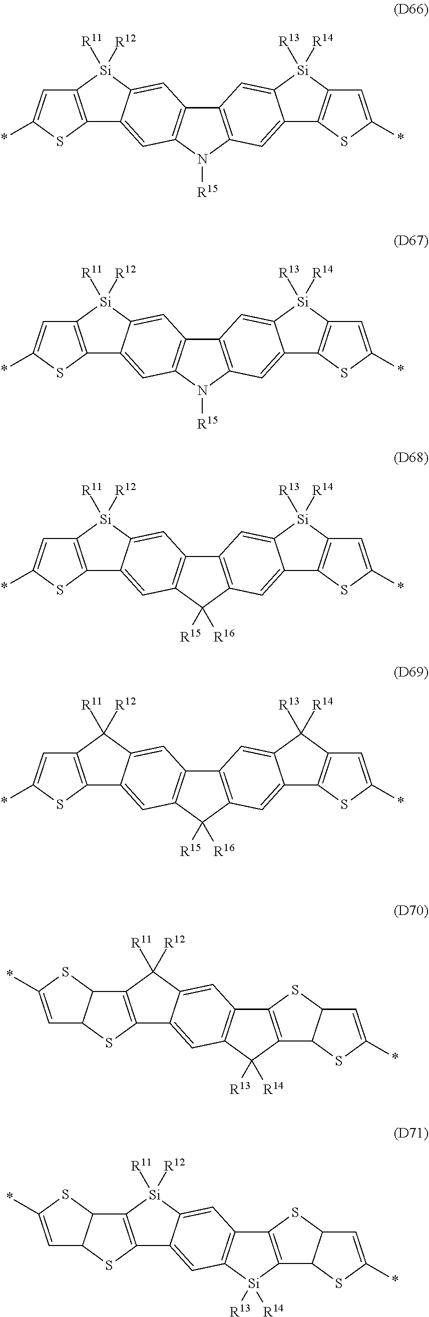

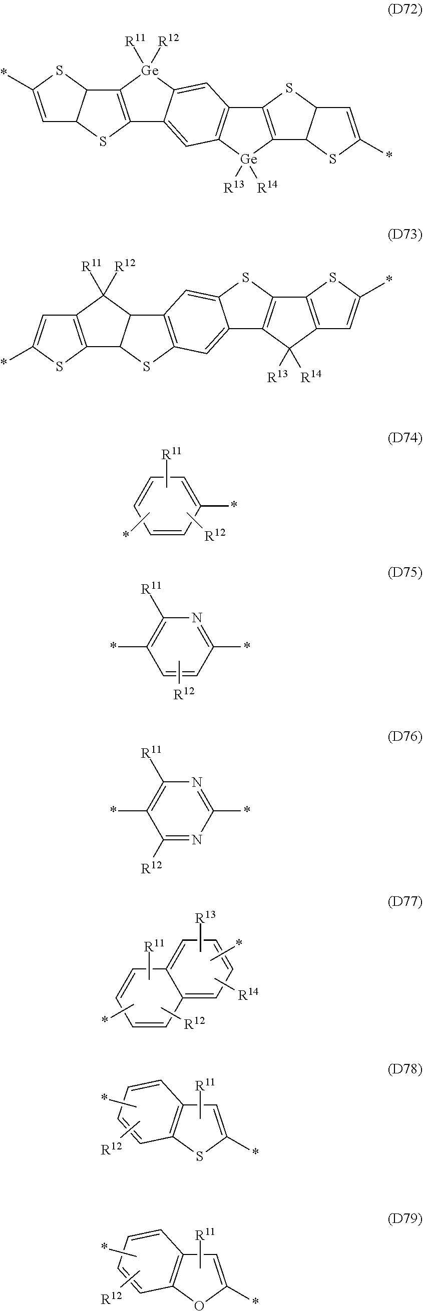

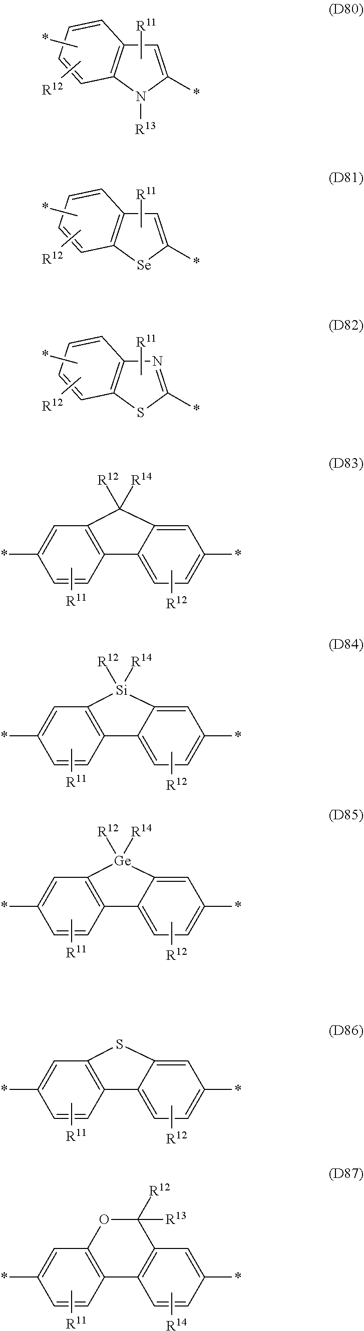

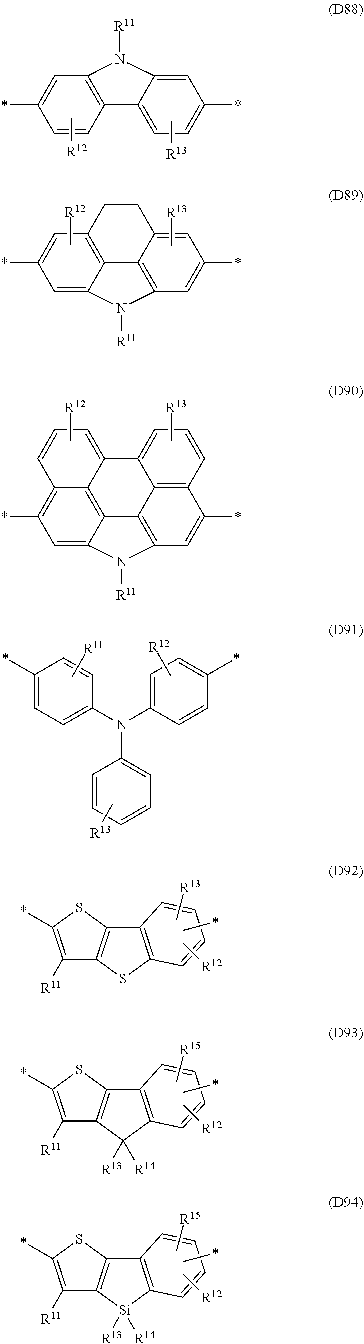

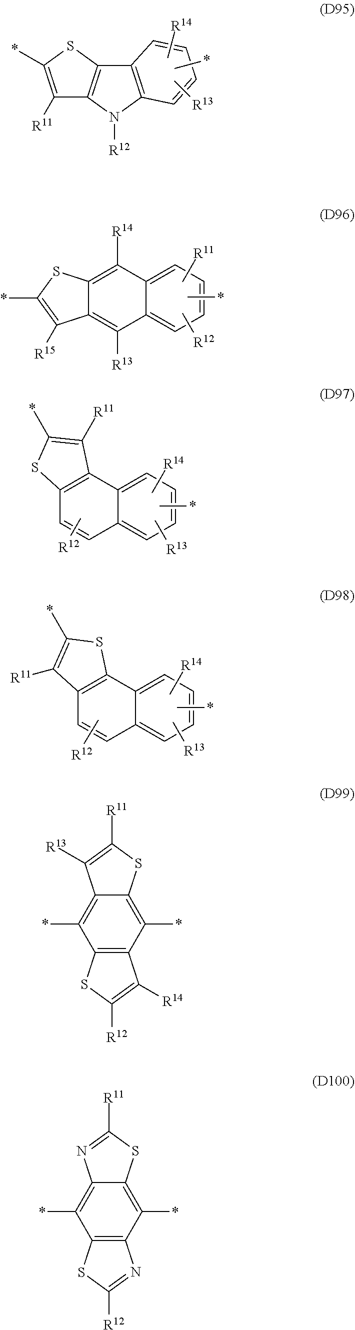

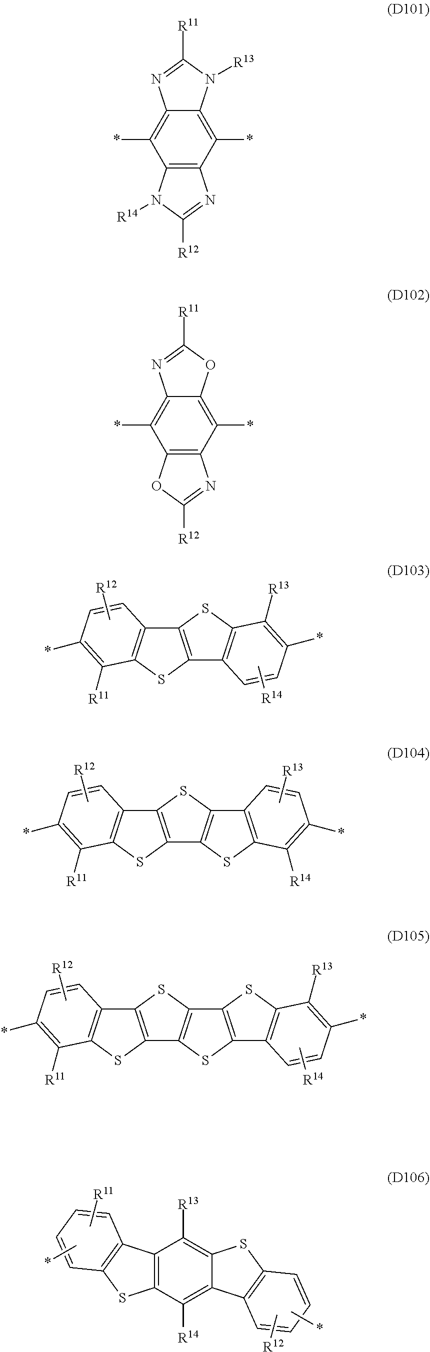

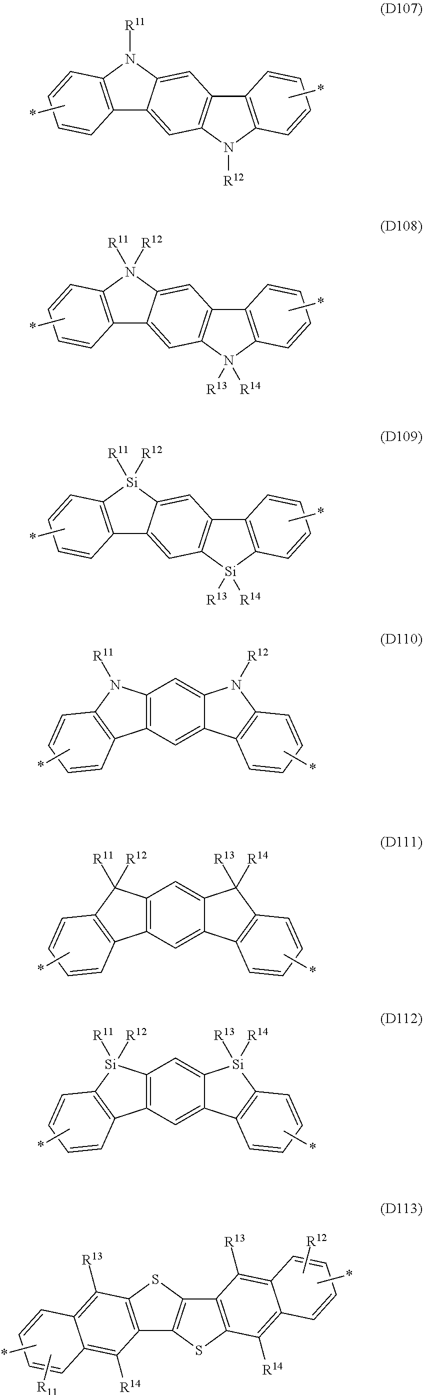

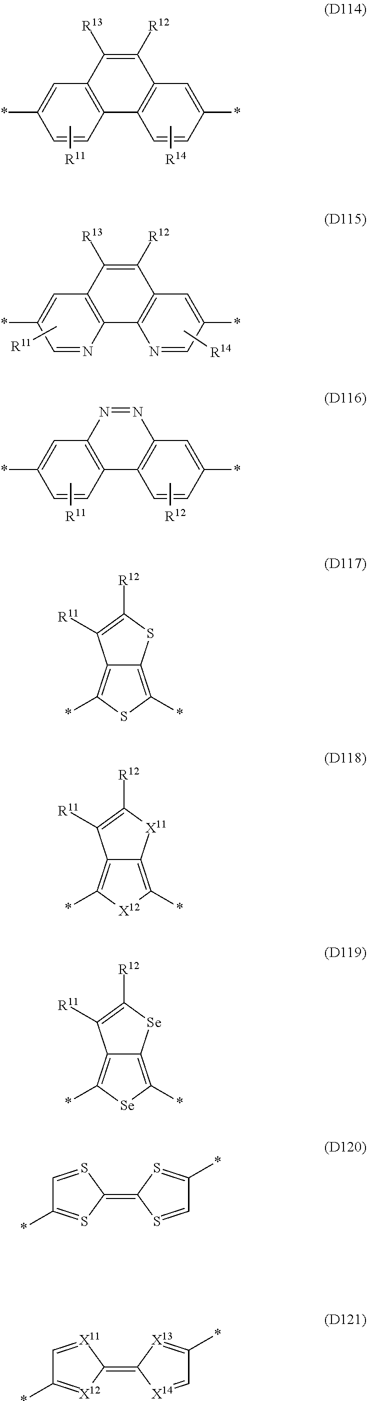

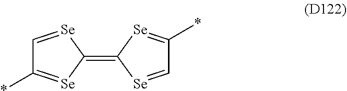

and their respective mirror images, wherein one of X¹¹ and X¹² is S and the other is Se, and one of X¹³ and X¹⁴ is S and the other is Se, and R¹¹, R¹², R¹³, R¹⁴, R¹⁵, R¹⁶, R¹⁷ and R¹⁸ are independently of each other selected from the group consisting of hydrogen, F, Br, Cl, —CN, —NC, —NCO, —NCS, —OCN, —SCN, —C(O)NR¹R², —C(O)X⁰, —C(O)R¹, —NH₂, —NR¹R², —SH, —SR¹, —SO₃H, —SO₂R¹, —OH, —NO₂, —CF₃, —SF₅, optionally substituted silyl or hydrocarbyl with 1 to 40 C atoms that is optionally substituted and optionally comprises one or more hetero atoms.

More preferably, the hole carrier polymer comprises a first monomeric unit selected from the group consisting of D30, D31, D32, D33, D34 and D35 and a second monomeric unit selected from the group consisting of D117, D118 and D119, wherein R¹¹, R¹², R¹³, R¹⁴, X¹¹ and X¹² are as defined above.

Even more preferably, the hole carrier polymer comprises a first monomeric unit being D30 and a second monomeric unit selected from the group consisting of D117, D118 and D119, or alternatively a first monomeric unit selected from the group consisting of D30, D31, D32, D33, D34 and D35 and a second monomeric unit being D117, wherein R¹¹, R¹², R¹³, R¹⁴, X¹¹ and X¹² are as defined above.

Still even more preferably, the hole carrier polymer comprises a first monomeric unit being D30 and a second monomeric unit being D117, wherein R¹¹, R¹², R¹³, R¹⁴, X¹¹ and X¹² are as defined above.

Most preferably, the hole carrier polymer comprises a first monomeric unit being D30 with R¹¹═R¹²═H and R¹³═R¹⁴═CH₂—CH(CH₂—CH₃)—(CH₂)₃—CH₃ and a second monomeric unit being D117 with R¹¹═H and R¹³═—(CH₂)ₚCH₃ or —(CF₂)ₚCF₃. wherein p is a number from 0 to 10, preferably from 2 to 8 and most preferably p is 5.

A specific example of a hole carrier polymer is

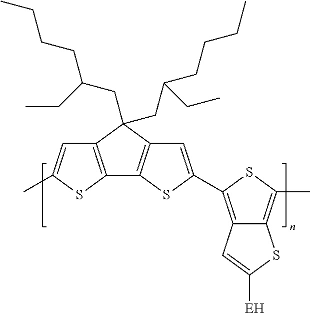

with EH being CH₂—CH(CH₂—CH₃)—(CH₂)₃—CH₃.

Preferably, the hole carrier polymers have a number average molecular weight of at least 1,000 Da, more preferably of at least 1,500 Da and most preferably of at least 2,000 Da.

Preferably, the hole carrier polymers have a number average molecular weight of at most 200,000 Da, more preferably of at most 150,000 Da, even more preferably of at most 100,000 Da, and most preferably of at most 50,000 Da.

In an exemplary embodiment, the reaction of the oxidizing agent and the hole carrier polymer can be as shown in Schema 1, below.

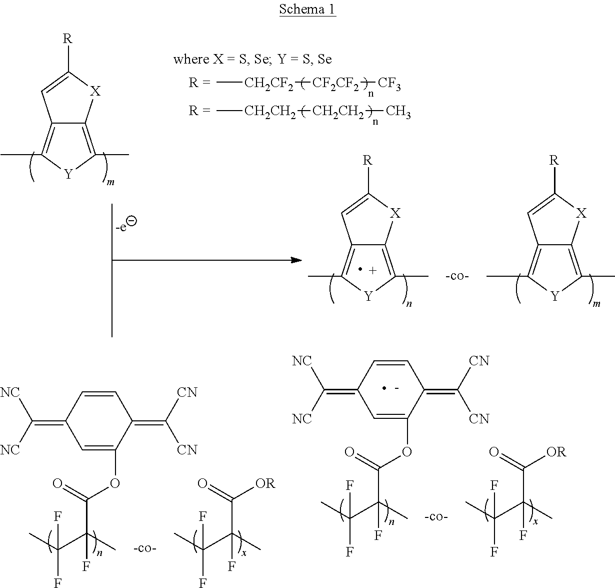

In other embodiments, a suitable hole carrier polymer using a terathofulvalene backbone can be obtained as shown in Schema 2, below.

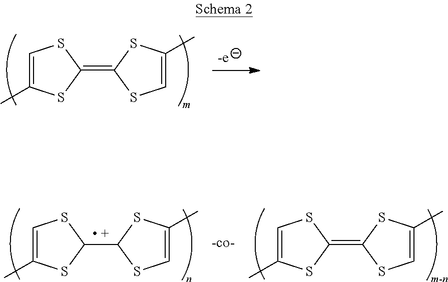

In an exemplary copolymer embodiment having a first monomer and a second monomer, the reaction of the oxidizing agent and the hole carrier polymer can be as shown in Schema 3, below.

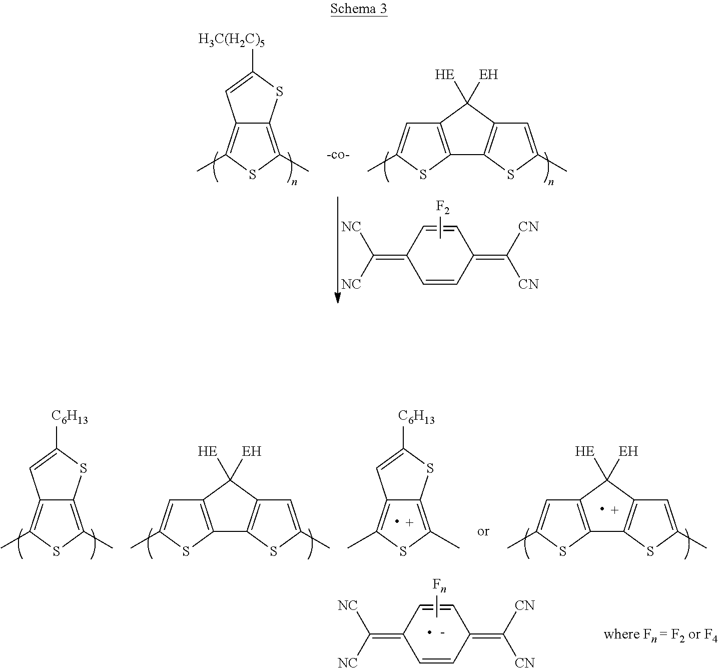

In certain preferred embodiments, as shown in Schema 3, above, BBT was used as a comonomer to enhance the solubility of the TT-R polymer; it too can be oxidized, and it becomes an integral part of the polaron. BBT-TTC6 is shown in the Schema 3, but most of the experimental work in the Examples, below, used BBT-TTEH. The TT family of polymers are relatively insoluble in all solvents, and they exhibit very low MWs, e.g., 2 k-4 kDa. Incorporation of BBT resulted in polymers with moderate molecular weights (MW=12 k-14 kDa) under our specific polymerization conditions. In the Examples, studies focused on the synthesis of a flexible chain polymer comprising pendant TCNQ derivatives. Cyclic voltametry of the neutral polymer lies between −4.9 and −5.1 eV.

In general, the mixture of a strong electron acceptor and a donor can spontaneously form a charge carrier complex (CTC), resulting in a p-type conductive polymer, i.e., a hole carrier polymer, that is not acidic. In embodiments having a co-polymer containing repeat units that have TCNQ pendants, the cation content on the donor chain can be adjusted. In other embodiments, hydrophobicity of the polymer can be adjusted by fluorinated pendants. In certain embodiments, hydrophobicity of the polymer can be adjusted by pendant hydrocarbon chains and the flexible polymer backbone. Exemplary embodiments are illustrated in Schema 4 and Schema 5, below.

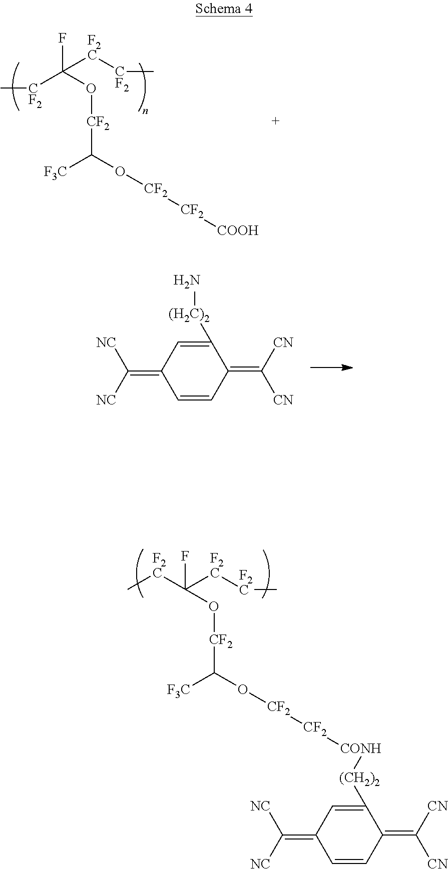

It is believed that the present hole carrier layers can be substituted for a conventional hole carrier layer, such as for example PEDOT doped with PSS, to provide a photovoltaic cell with sufficiently high energy conversion and/or with sufficiently high lifetime due to the lack of corrosive substances. It is also believed that the present hole carrier layer allows for the production of sufficiently thick layers, thus offering the possibility to, avoid, or at least reduce, shunting, which may produce short circuits, essentially by creating holes, during the production of photovoltaic cells on a large scale.

In some embodiments the hole carrier layer can optionally comprise a binder. Preferably, such binder is a polymer. Examples of suitable polymers include acrylic resins, ionic resins, and polymers comprising an electron accepting group.

Exemplary acrylic resins include methyl methacrylate homopolymers and copolymers, ethyl methacrylate homopolymers and copolymers, butyl methacrylate (e.g., n-butyl methacrylate or iso-butyl methacrylate) homopolymers and copolymers. Commercial examples of such acrylic resins include an ELVACITE series of polymers available from Lucite International (Cordova, Tenn.).

In general, ionic polymers suitable for use as a binder can include positive and/or negative groups. Exemplary positive groups include ammonium groups (e.g., tetramethylammonium), phosphonium, and pyridinium. Exemplary negative groups include carboxylate, sulfonate, phosphate, and boronate.

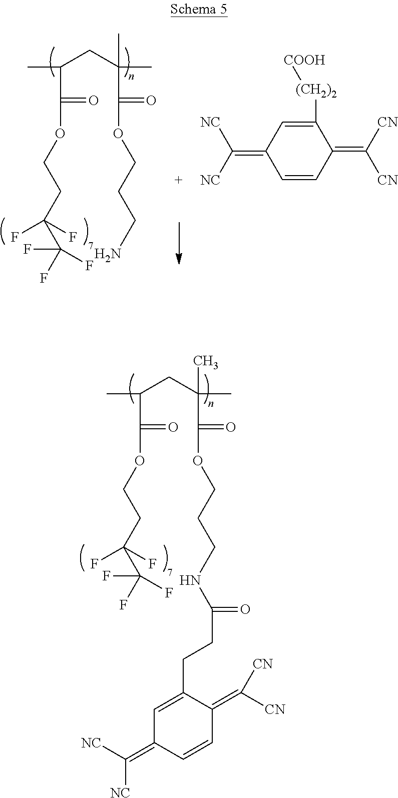

Without wishing to be bound by theory, it is believed that polymers containing an electron accepting group can be fluoro-containing polymers and cyano-containing polymers. Fluoro-containing polymers can be completely or partially fluorinated polymers. Examples of completely fluorinated polymers include poly(hexafluoropropylene), poly(perfluoroalkyl vinyl ether)s, poly(perfluoro-(2,2-dimethyl-1,3-dioxole), and poly(tetrafluoroethylene). Examples of partially fluorinated polymers include poly(vinyl fluoride), poly(vinylidene fluoride), partially fluorinated polysiloxanes, partially fluorinated polyacrylates, and partially fluorinated polymethacrylates, partially fluorinated polystyrenes, and partially fluorinated poly(tetrafluoroethylene) copolymers Commercial examples of fluoro-containing polymers include TEFLON, TEFLON AF, NAFION, and TEDLAR series of polymers available from E.I. du Pont de Nemours and Company (Wilmington, Del.), a KYNAR series of polymers available from Atochem (Philadelphia, Pa.), and a CYTOP series of polymers available from Bellex International Corporation (Wilmington, Del.). Fluorinated ionic polymers (e.g., polymers containing carboxyl, sulfonic acid, phosphonic acid) can also be used as a suitable fluoro-containing polymer for the binder. Other suitable electron accepting groups include rt-electron accepting groups (e.g., pentafluoro phenyl and pentafluoro benzyol) and boronate groups (e.g., pentafluoro phenyl boronate).

In some embodiments, the binder can include a sol gel. Without wishing to be bound by theory, it is believed that a hole carrier layer containing a sol gel as a binder can exhibit excellent mechanical properties and can form a very hard film. Such a layer can serve as an effective solvent barrier for the underlying layer during manufacturing of a photovoltaic cell.

In some embodiments, the sol gel can be a p-type semiconductor (i.e. a p-type sol gel). The p-type sol gel can be formed from a p-type sol, such as those containing vanadic acid, vanadium(V) chloride, vanadium(V) alkoxide, nickel(II) chloride, nickel(II) alkoxide, copper(II) acetate, copper(II) alkoxide, molybdenum(V) chloride, molybdenum(V) alkoxide, or a combination thereof.

In some embodiments, the binder can be at least about 1 vol % (e.g., at least about 2 vol %, at least about 5 vol %, at least about 10 vol %, or at least about 20 vol %) and/or at most about 50 vol % (e.g., at most about 40 vol %, at most about 30 vol %, at most about 25 vol %, or at most about 15 vol %) of hole carrier layer 150.

The thickness of the hole carrier layer may be varied as desired. The thickness may for example depend upon the work functions of the neighboring layers in a photovoltaic cell. Preferably, the layer comprising the hole carrier polymer has a thickness of at least 5 nm and/or of at most 500 nm.

In some embodiments, the photovoltaic cell comprises a photoactive layer, which in turn comprises an electron donor material and an electron acceptor material.

The electron donor material may include a polymer selected from the group consisting of polythiophenes, polyanilines, polycarbazoles, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxalines, polybenzoisothiazoles, polybenzothiazoles, polythienothiophenes, poly(thienothiophene oxide)s, polydithienothiophenes, poly(dithienothiophene oxide)s, polytetrahydroisoindoles, polyfluorenes, and copolymers thereof. For example, the electron donor material can include a polythiophene or a polycyclopentadithiophene. The electron acceptor material can include a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof. For example, the electron acceptor material can include a substituted fullerene.

In general, the method of preparing hole carrier layer 150 can vary as desired. In some embodiments, hole carrier layer 150 can be prepared via a gas phase-based coating process, such as chemical or physical vapor deposition processes. A gas phase-based coating process generally involves evaporating the materials to be coated (e.g., in vacuum) and apply the evaporated materials to a surface (e.g., by sputtering).

In some embodiments, hole carrier layer 150 can be prepared via a liquid-based coating process. The term “liquid-based coating process” mentioned herein refers to a process that uses a liquid-based coating composition. Examples of the liquid-based coating composition include solutions, dispersions, and suspensions. The liquid-based coating process can be carried out by using at least one of the following processes: solution coating, ink jet printing, spin coating, dip coating, knife coating, bar coating, spray coating, roller coating, slot coating, gravure coating, flexographic printing, or screen printing. Examples of liquid-based coating processes have been described in, for example, commonly-owned co-pending U.S. Application Publication No. 2008-0006324. Without wishing to be bound by theory, it is believed that forming hole carrier layer 150 by a liquid-based coating process can result in a film with a sufficiently large thickness. Such a hole carrier layer can minimize shunting during manufacturing of photovoltaic cells in a large scale.

Generally, the hole carrier polymer and the oxidizing agent may either first be mixed and then dissolved in a solvent, or they may be dissolved separately in a common solvent or different solvents and then mixed. After mixing the resulting solution is coated over the layer underneath by a liquid coating process as defined herein. Such an approach particularly suited for the oxidizing agents selected from the group consisting of (I-a), (I-b), (I-e), (I-f), (II) and (III) but may also be used with any other of the presently used hole carrier polymers and oxidizing agents.

Alternatively, the hole carrier polymer may be dissolved in a first solvent, coated over the layer underneath and dried. Subsequently the solution of oxidizing agent in a second solvent is coated over the layer of hole carrier polymer. The first and second solvent may be the same or different.

Thus, in one aspect the present method for manufacturing the article of the present invention comprises the steps of
(a) mixing the hole carrier polymer and the oxidizing agent and dissolving them together in a solvent, or dissolving the hole carrier polymer in a first solvent and the oxidizing agent in a second solvent and then mixing the two solutions; and
(b) subsequently coating the resulting solution from step (a) over a layer underneath,
   wherein the first and second solvent may be the same or different.

In another aspect the present method for manufacturing the article of the present invention comprises the steps of

(a) dissolving the hole carrier polymer in a first solvent to obtain a first solution;
(b) coating the first solution over a layer underneath;
(c) drying the resulting layer of hole carrier polymer;
(d) dissolving the oxidizing agent in a second solvent to obtain a second solution; and
(c) coating the second solution over the layer of hole carrier polymer obtained in step (c);
wherein the first and second solvent may be the same or different.

As used above, the “layer underneath” may for example be a photoactive layer, e.g., in a photovoltaic cell of “inverted cell architecture”. Alternatively said layer underneath may be the first electrode, such that the photoactive layer will eventually be on top of the hole carrier layer. Such an approach particularly suited for oxidizing agents selected from the group consisting of (I) and (III) but also be used with any other of the presently used hole carrier polymers and oxidizing agents.

It is also possible to dissolve the hole carrier polymer and the oxidizing agent in separate solvents, and then in a first step to coat the layer underneath with the solution of the hole carrier polymer, dry said layer, and then deposit the solution of oxidizing agent onto the hole carrier polymer.

The solvents used in the present invention are preferably organic solvents. Exemplary organic solvents are selected from the group consisting of aliphatic hydrocarbons, chlorinated hydrocarbons, aromatic hydrocarbons, ketones, ethers and mixtures thereof. Additional solvents which can be used include 1,2,4-trimethylbenzene, 1,2,3,4-tetra-methyl benzene, pentylbenzene, mesitylene, cumene, cymene, cyclohexylbenzene, diethylbenzene, tetralin, decalin, 2,6-lutidine, 2-fluoro-m-xylene, 3-fluoro-o-xylene, 2-chlorobenzotrifluoride, N,N-dimethylformamide, 2-chloro-6-fluorotoluene, 2-fluoroanisole, anisole, 2,3-dimethylpyrazine, 4-fluoroanisole, 3-fluoroanisole, 3-trifluoro-methylanisole, 2-methylanisole, phenetol, 4-methylanisole, 3-methylanisole, 4-fluoro-3-methylanisole, 2-fluorobenzonitrile, 4-fluoroveratrol, 2,6-dimethylanisole, 3-fluorobenzo-nitrile, 2,5-dimethylanisole, 2,4-dimethylanisole, benzonitrile, 3,5-dimethylanisole, N,N-dimethylaniline, ethyl benzoate, 1-fluoro-3,5-dimethoxy-benzene, 1-methylnaphthalene, N-methylpyrrolidinone, 3-fluorobenzo-trifluoride, benzotrifluoride, dioxane, trifluoromethoxy-benzene, 4-fluorobenzotrifluoride, 3-fluoropyridine, toluene, 2-fluoro-toluene, 2-fluorobenzotrifluoride, 3-fluorotoluene, 4-isopropylbiphenyl, phenyl ether, pyridine, 4-fluorotoluene, 2,5-difluorotoluene, 1-chloro-2,4-difluorobenzene, 2-fluoropyridine, 3-chlorofluoro-benzene, 1-chloro-2,5-difluorobenzene, 4-chlorofluorobenzene, chloro-benzene, o-dichlorobenzene, 2-chlorofluorobenzene, p-xylene, m-xylene, o-xylene or mixture of o-, m-, and p-isomers.

For a solution of the reaction production between the hole carrier polymer and the oxidizing agent methylene chloride (CH₂Cl₂), ortho-dichlorobenzene, meta-dichlorobenzene, para-dichlorobenzene and a blend of methylene chloride and n-propanol in a volume ratio of 2:1 have been found particularly useful.

If a binder is to be present in the hole carrier layer, the solution of hole carrier polymer may additionally comprise the binder.

Turning to other components of photovoltaic cell 100, substrate 110 is generally formed of a transparent material. As referred to herein, a transparent material is a material which, at the thickness used in a photovoltaic cell 100, transmits at least about 60% (e.g., at least about 70%, at least about 75%, at least about 80%, at least about 85%) of incident light at a wavelength or a range of wavelengths used during operation of the photovoltaic cell. Exemplary materials from which substrate 110 can be formed include polyethylene terephthalates, polyimides, polyethylene naphthalates, polymeric hydrocarbons, cellulosic polymers, polycarbonates, polyamides, polyethers, and polyether ketones. In certain embodiments, the polymer can be a fluorinated polymer. In some embodiments, combinations of polymeric materials are used. In certain embodiments, different regions of substrate 110 can be formed of different materials.

In general, substrate 110 can be flexible, semi-rigid or rigid (e.g., glass). In some embodiments, substrate 110 has a flexural modulus of less than about 5,000 mPa (e.g., less than about 1,000 mPa or less than about 500 mPa). In certain embodiments, different regions of substrate 110 can be flexible, semi-rigid, or inflexible (e.g., one or more regions flexible and one or more different regions semi-rigid, one or more regions flexible and one or more different regions inflexible).

Typically, substrate 110 has a thickness at least about one micron (e.g., at least about five microns or at least about 10 microns) and/or at most about 1,000 microns (e.g., at most about 500 microns, at most about 300 microns, at most about 200 microns, at most about 100 microns, or at most about 50 microns).

Generally, substrate 110 can be colored or non-colored. In some embodiments, one or more portions of substrate 110 is/are colored while one or more different portions of substrate 110 is/are non-colored.

Substrate 110 can have one planar surface (e.g., the surface on which light impinges), two planar surfaces (e.g., the surface on which light impinges and the opposite surface), or no planar surface. A non-planar surface of substrate 110 can, for example, be curved or stepped. In some embodiments, a non-planar surface of substrate 110 is patterned (e.g., having patterned steps to form a Fresnel lens, a lenticular lens or a lenticular prism).

Electrode 120 is generally formed of an electrically conductive material. Exemplary electrically conductive materials include electrically conductive metals, electrically conductive alloys, electrically conductive polymers, and electrically conductive metal oxides. Exemplary electrically conductive metals include gold, silver, copper, aluminum, nickel, palladium, platinum, and titanium. Exemplary electrically conductive alloys include stainless steel (e.g., 332 stainless steel, 316 stainless steel), alloys of gold, alloys of silver, alloys of copper, alloys of aluminum, alloys of nickel, alloys of palladium, alloys of platinum, and alloys of titanium. Exemplary electrically conducting polymers include polythiophenes (e.g., doped poly(3,4-ethylenedioxythiophene) (doped PEDOT)), polyanilines (e.g., doped polyanilines), polypyrroles (e.g., doped polypyrroles). Exemplary electrically conducting metal oxides include indium tin oxide, fluorinated tin oxide, tin oxide and zinc oxide. In some embodiments, combinations of electrically conductive materials are used.

In some embodiments, electrode 120 can include a mesh electrode. Examples of mesh electrodes are described in U.S. Patent Application Publications Nos. 2004-0187911 and 2006-0090791.

In some embodiments, a combination of the materials described above can be used to form electrode 120.

Optionally, photovoltaic cell 100 can include a hole blocking layer 130. The hole blocking layer is generally formed of a material that, at the thickness used in photovoltaic cell 100, transports electrons to electrode 120 and substantially blocks the transport of holes to electrode 120. Examples of materials from which the hole blocking layer can be formed include LiF, metal oxides (e.g., zinc oxide or titanium oxide), and amines (e.g., primary, secondary, or tertiary amines). Examples of amines suitable for use in a hole blocking layer have been described, for example, in U.S. Application Publication No. 2008-0264488, now U.S. Pat. No. 8,242,356.

Without wishing to be bound by theory, it is believed that, when photovoltaic cell 100 includes a hole blocking layer made of amines, the hole blocking layer can facilitate the formation of ohmic contact between photoactive layer 140 and electrode 120 without being exposed to UV light, thereby reducing damage to photovoltaic cell 100 resulting from UV exposure.

In some embodiments, hole blocking layer 130 can have a thickness of at least about 1 nm (e.g., at least about 2 nm, at least about 5 nm, or at least about 10 nm) and/or at most about 50 nm (e.g., at most about 40 nm, at most about 30 nm, at most about 20 nm, or at most about 10 nm).

Photoactive layer 140 generally contains an electron acceptor material (e.g., an organic electron acceptor material) and an electron donor material (e.g., an organic electron donor material).

Examples of electron acceptor materials include fullerenes, inorganic nanoparticles, oxadiazoles, discotic liquid crystals, carbon nanorods, inorganic nanorods, polymers containing moieties capable of accepting electrons or forming stable anions (e.g., polymers containing CN groups or polymers containing CF3 groups), and combinations thereof. In some embodiments, the electron acceptor material is a substituted fullerene (e.g., a phenyl-C61-butyric acid methyl ester (PCBM-C60) or a phenyl-C71-butyric acid methyl ester (PCBM-C70)). In some embodiments, a combination of electron acceptor materials can be used in photoactive layer 140.

Examples of electron donor materials include conjugated polymers, such as polythiophenes, polyanilines, polycarbazoles, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxalines, polybenzoisothiazoles, polybenzothiazoles, polythienothiophenes, poly(thienothiophene oxide)s, polydithienothiophenes, poly(dithienothiophene oxide)s, polyfluorenes, polytetrahydroisoindoles, and copolymers thereof. In some embodiments, the electron donor material can be polythiophenes (e.g., poly(3-hexylthiophene)), polycyclopentadithiophenes, and copolymers thereof. In certain embodiments, a combination of electron donor materials can be used in photoactive layer 140.

Examples of other polymers suitable for use in photoactive layer 140 have been described in, e.g., U.S. Pat. Nos. 7,781,673 and 7,772,485, PCT Application No. PCT/US2011/020227, and U.S. Application Publication Nos. 2010-0224252, 2010-0032018, 2008-0121281, 2008-0087324, 2007-0020526, and 2007-0017571.

Electrode 160 is generally formed of an electrically conductive material, such as one or more of the electrically conductive materials described above with respect to electrode 120. In some embodiments, electrode 160 is formed of a combination of electrically conductive materials. In certain embodiments, electrode 160 can be formed of a mesh electrode.

Substrate 170 can be identical to or different from substrate 110. In some embodiments, substrate 170 can be formed of one or more suitable polymers, such as the polymers used in substrate 110 described above.

In general, the methods of preparing each of layers 120, 130, 140, and 160 in photovoltaic cell 100 can vary as desired. In some embodiments, layer 120, 130, 140, or 160 can be prepared by a gas phase based coating process or a liquid-based coating process, such as those described above.

In some embodiments, when a layer (e.g., layer 120, 130, 140, or 160) includes inorganic semiconductor material, the liquid-based coating process can be carried out by (1) mixing the inorganic semiconductor material with a solvent (e.g., an aqueous solvent or an anhydrous alcohol) to form a dispersion, (2) coating the dispersion onto a substrate, and (3) drying the coated dispersion.

In general, the liquid-based coating process used to prepare a layer (e.g., layer 120, 130, 140, or 160) containing an organic semiconductor material can be the same as or different from that used to prepare a layer containing an inorganic semiconductor material. In some embodiments, to prepare a layer including an organic semiconductor material, the liquid-based coating process can be carried out by mixing the organic semiconductor material with a solvent (e.g., an organic solvent) to form a solution or a dispersion, coating the solution or dispersion on a substrate, and drying the coated solution or dispersion.

In some embodiments, photovoltaic cell 100 can be prepared in a continuous manufacturing process, such as a roll-to-roll process, thereby significantly reducing the manufacturing cost. Examples of roll-to-roll processes have been described in, for example, commonly-owned U.S. Pat. Nos. 7,476,278 and 8429,616.

While certain embodiments have been disclosed, other embodiments are also possible.

In some embodiments, photovoltaic cell 100 includes a cathode as a bottom electrode (i.e. electrode 120) and an anode as a top electrode (i.e. electrode 160). In some embodiments, photovoltaic cell 100 can include an anode as a bottom electrode and a cathode as a top electrode.

In some embodiments, photovoltaic cell 100 can include the layers shown in FIG. 1 in a reverse order. In other words, photovoltaic cell 100 can include these layers from the bottom to the top in the following sequence: a substrate 170, an electrode 160, a hole carrier layer 150, a photoactive layer 140, an optional hole blocking layer 130, an electrode 120, and a substrate 110.

In some embodiments, one of substrates 110 and 170 can be transparent. In other embodiments, both of substrates 110 and 170 can be transparent.

In some embodiments, the above disclosed hole carrier layer can also be used in a system in which two photovoltaic cells share a common electrode. Such a system is also known as tandem photovoltaic cell. Exemplary tandem photovoltaic cells have been described in, e.g., U.S. Application Publication Nos. 2009-0211633, 2007-0181179, 2007-0246094, and 2007-0272296.

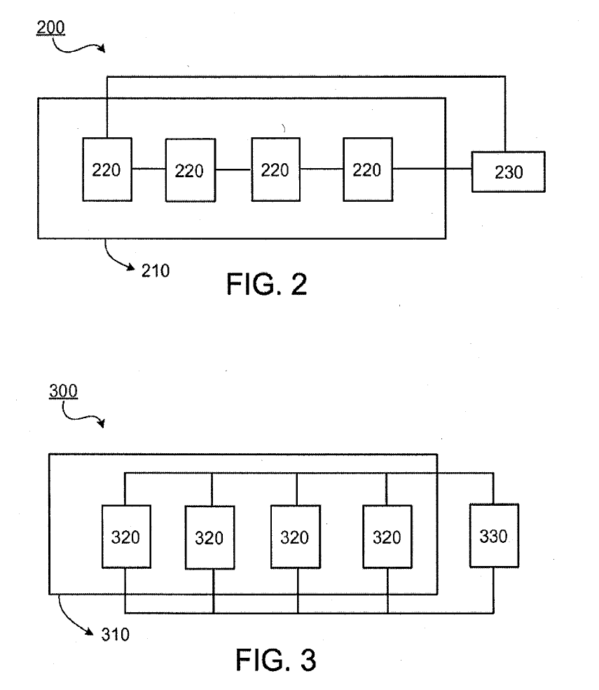

In some embodiments, multiple photovoltaic cells can be electrically connected to form a photovoltaic system. As an example, FIG. 2 is a schematic of a photovoltaic system 200 having a module 210 containing a plurality of photovoltaic cells 220. Cells 220 are electrically connected in series, and system 200 is electrically connected to a load 230. As another example, FIG. 3 is a schematic of a photovoltaic system 300 having a module 310 that contains a plurality of photovoltaic cells 320. Cells 320 are electrically connected in parallel, and system 300 is electrically connected to a load 330. In some embodiments, some (e.g., all) of the photovoltaic cells in a photovoltaic system can be disposed on one or more common substrates. In certain embodiments, some photovoltaic cells in a photovoltaic system are electrically connected in series, and some of the photovoltaic cells in the photovoltaic system are electrically connected in parallel.

While organic photovoltaic cells have been described, other photovoltaic cells can also be prepared based on the hole carrier layer described herein. Examples of such photovoltaic cells include dye sensitized photovoltaic cells and inorganic photoactive cells with a photoactive material formed of amorphous silicon, cadmium selenide, cadmium telluride, copper indium selenide, and copper indium gallium selenide.

While photovoltaic cells have been described above, in some embodiments, the present hole carrier layer can be used in other devices and systems. For example, the present hole carrier layer can be used in suitable organic semiconductive devices, such as field effect transistors, photodetectors (e.g., IR detectors), photovoltaic detectors, imaging devices (e.g., RGB imaging devices for cameras or medical imaging systems), light emitting diodes (LEDs) (e.g., organic LEDs (OLEDs) or IR or near IR LEDs), lasing devices, conversion layers (e.g., layers that convert visible emission into IR emission), amplifiers and emitters for telecommunication (e.g., dopants for fibers), storage elements (e.g., holographic storage elements), and electrochromic devices (e.g., electrochromic displays).

The contents of all publications cited herein (e.g., patents, patent application publications, and articles) are hereby incorporated by reference in their entirety.

The following examples are illustrative and not intended to be limiting.

### EXAMPLES

As noted above, in most of the following Examples the compound BBT-TTEH was used as hole carrier polymer and compounds (I-a), (I-b), (II) and (III) as oxidizing agents, wherein in compound (III) X¹═X²═S.

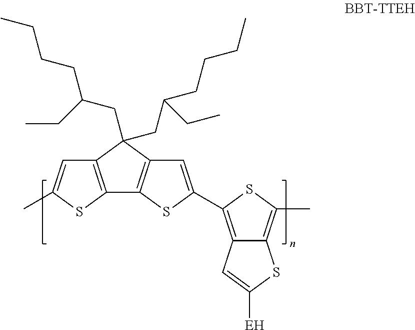

### Example 1

### Reaction of F4-TCNQ and BBT-TTEH

A TT polymer with ethyl-hexyl substituents was reacted with F4-TCNQ and the progress of the reaction was followed with uv/vis spectroscopy. The reaction appeared to be completed after 15-20 mole % of F4-TCNQ on the BBT-TTEH. The F4TCNQ is a strong Lewis acid capable of oxidizing TT polymers.

F4-TCNQ (tetrafluoro-tetracyano-quinodimethane, compound (I-a)) was dissolved in ortho-dichlorobenzene at 4.33 millimolar concentration. A solution of BBT-TTEH in ortho-dichlorobenzene was prepared at 2.04 millimolar concentration, based on the MW of the repeating unit. The solution of BBT-TTEH was diluted to 1/10^{th} of the initial concentration and added to a cuvette. Aliquots of 10 ml of the F4-TCNQ solution were added to the solution of BBT-TTEH with UV/VIS spectra taken after each addition. The spectrum of the F4TCNQ was taken of a 1/10^{th} diluted sample, 0.433 millimolar. The titration data are summarized in Table 1, below.

TABLE 1
Summary of F4-TCNQ addition to polymer.

| Compound | FW | Aim Conc | Volume | Equivs | % of BBT-TTEH |
|---|---|---|---|---|---|
| BBT-TTEH | 650 | 0.00002042 | 2700 | 55.1 | 100 |
| F4TCNQ | 276 | 0.0004328 | 10 | 4.3 | 7.85% |
| F4TCNQ | 276 | 0.0004328 | 20 | 8.7 | 15.70% |
| F4TCNQ | 276 | 0.0004328 | 30 | 13.0 | 23.55% |
| F4TCNQ | 276 | 0.0004328 | 40 | 17.3 | 31.40% |
| F4TCNQ | 276 | 0.0004328 | 50 | 21.6 | 39.25% |
| F4TCNQ | 276 | 0.0004328 | 60 | 26.0 | 47.10% |
| F4TCNQ | 276 | 0.0004328 | 70 | 30.3 | 54.95% |
| F4TCNQ | 276 | 0.0004328 | 90 | 39.0 | 70.65% |
| F4TCNQ | 276 | 0.0004328 | 110 | 47.6 | 86.35% |
| F4TCNQ | 276 | 0.0004328 | 140 | 60.592 | 109.90% |

It was observed that after only about 15 to 20 mol % of F4-TCNQ relative to BBT-TTEH had been added, the reaction appeared complete, as seen in the spectra. The BBT-TTEH signal disappeared and reaction products are seen as the reduced form of F4-TCNQ between 700 and 900 nm and the polymer product with a peak at about 418 nm, which then starts disappearing underneath the peak of neutral (unreacted) F4-TCNQ) at 392 nm.

### Example 2

### Reaction of TCNQ and BBT-TTEH

Because of the desire to maintain reactive sites on the reaction product, reacting the non-substituted TCNQ with the BBT-TTEH was studied. Due to the low solubility of TCNQ in oetho-dichlorobenzene (o-DCB), an 80/20 blend of dimethoxy ethane and acetonitrile was used. The TCNQ readily dissolved in this solvent mixture, but the BBT-TTEH appeared to form a combination of solution and fine particle dispersion after mixing overnight as seen in the baseline BBT-TTEH only spectrum.

TCNQ was dissolved in an 80:20-blend of dimethoxyethane and acetonitrile to result in a TCNQ-concentration of 0.4 millimolar. This solution was diluted to ⅕^{th} for taking an initial spectrum. The BBT-TTEH was prepared at approximately 0.2 millimolar and in the same solvent blended with overnight stirring. The resulting blue fluid scattered light somewhat, indicating that there was some dissolution and some fine particles present.

As the TCNQ was added incrementally to the polymer solution up to about 12 mole % relative to BBT-TTEH, there was no sign of any new reaction product peak(s), but the TCNQ anion peaks increased steadily in spite of the fact that there was no apparent loss of BBT-TTEH due to reaction. The titration data are summarized in Table 2, below.

TABLE 2
TCNQ addition to BBT-TTEH

| Compound | FW | Aim Conc | Volume | Equivs | % of BBT-TTEH |
|---|---|---|---|---|---|
| BBT-TTEH | 650 | 0.000185 | 2700 | 499.5 | 100 |
| TCNQ | 202 | 0.000441 | 2 | 0.9 | 0.18% |
| TCNQ | 202 | 0.000441 | 12 | 5.3 | 1.06% |
| TCNQ | 202 | 0.000441 | 22 | 9.7 | 1.94% |
| TCNQ | 202 | 0.000441 | 32 | 14.1 | 2.83% |
| TCNQ | 202 | 0.000441 | 42 | 18.5 | 3.71% |
| TCNQ | 202 | 0.000441 | 52 | 22.9 | 4.59% |
| TCNQ | 202 | 0.000441 | 72 | 31.8 | 6.36% |
| TCNQ | 202 | 0.000441 | 92 | 40.6 | 8.13% |
| TCNQ | 202 | 0.000441 | 112 | 49.4 | 9.90% |
| TCNQ | 202 | 0.000441 | 132 | 58.2516 | 11.66% |

### Example 3

### Reaction of F2-TCNQ and BBT-TTEH

The study was conducted similarly to Example 1 with the major difference that instead of F4-TCNQ, F2-TCNQ was used. Dilute solutions of both BBT-TTEH and F2-TCNQ were prepared. Reaction progress was followed again by UV/VIS-spectroscopy following each addition of F2-TCNQ solution to the solution of BBT-TTEH. Table 3, below, summarizes the titration data.

When F2-TCNQ was added to BBT-TTEH, the main BBT-TTEH peak decreased significantly after the addition of only 8.5 mole % of F2-TCNQ. The reaction did not run to completion as it did with F4-TCNQ. The F2-TCNQ does react very well as shown by the significant decrease of the BBT-TTEH peak, indicating that the reaction approaches complete oxidation.

TABLE 3
Addition schedule for F2-TCNQ oxidation of BBT-TTEH.

| Compound | FW | Aim Conc | Vol. | Equivs | % of BBT-TTEH |
|---|---|---|---|---|---|
| BBT-TTEH | 650 | 1.81154E−05 | 2700 | 48.9 | 100 |
| F2TCNQ | 240 | 0.000415 | 10 | 4.2 | 8.48% |
| F2TCNQ | 240 | 0.000415 | 20 | 8.3 | 16.97% |
| F2TCNQ | 240 | 0.000415 | 30 | 12.5 | 25.45% |
| F2TCNQ | 240 | 0.000415 | 40 | 16.6 | 33.94% |
| F2TCNQ | 240 | 0.000415 | 50 | 20.8 | 42.42% |
| F2TCNQ | 240 | 0.000415 | 60 | 24.9 | 50.91% |
| F2TCNQ | 240 | 0.000415 | 70 | 29.1 | 59.39% |
| F2TCNQ | 240 | 0.000415 | 90 | 37.4 | 76.36% |
| F2TCNQ | 240 | 0.000415 | 110 | 45.7 | 93.33% |
| F2TCNQ | 240 | 0.000415 | 140 | 58.1 | 118.79% |

### Example 4

### Resistivity of Coatings Made with the Reaction Production of BBT-TTEH and F4-TCNQ

Using toluene as the solvent for both components of the reaction, 2 and 3 millimolar solutions of F4-TCNQ and a 30 millimolar solution of BBT-TTEH were prepared. The solution of F4-TCNQ fluid required heating to 90° C. for complete dissolution. It was found that more than 20 mole % of F4-TCNQ on BBT-TTEH had to be added before measurable resistivity of the coatings could be obtained. A series of solutions was prepared as described in Table 4 below.

TABLE 4

| | | | | | | % F4TCNQ | |
|---|---|---|---|---|---|---|---|
| Exp | | | Aim | Vol- | | on | Total |
| # | Compound | FW | Conc | ume | Equivs | BBT-TTEH | Vol |
| | BBT-TTEH | 650 | 0.02 | 2000 | 40000 | — | |
| 1 | F4TCNQ | 276 | 0.002 | 5000 | 10000 | 25.00% | 7 |
| 2 | F4TCNQ | 276 | 0.002 | 6000 | 12000 | 30.00% | 8 |
| 3 | F4TCNQ | 276 | 0.003 | 4500 | 13500 | 33.75% | 6.5 |
| 4 | F4TCNQ | 276 | 0.003 | 5000 | 15000 | 37.50% | 7 |

The above fluids were coated over ST-504 (heat stabilized PET) for various numbers of passes and surface resistivity and optical density were measured. A control lab HIL fluid was also coated for comparison with 4 passes at 10 mm/second. All of the above fluids were agitated at 90° C. and coated on a 65° C. heated block. The results are presented in Table 5, below.

TABLE 5

| | # Passes/blade | Optical | | |
|---|---|---|---|---|
| Fluid | spd. | Density | Resistivity | Color of film |
| Exp #1 | 3 at 40 mm/s | 0.12 | No reading | Blue |
| Exp #2 | 4 at 40 mm/s | 0.11 | No reading | Blue-grey |
| Exp #3 | 3 at 40 mm/s | 0.14 | 19 Mohm/square | Blue-grey |
| Exp #4 | 4 at 40 mm/s | 0.12 | 19 Mohm/square | Grey |
| 1% KHIL | 4 at 10 mm/s | 0.06 | 18 Mohm/square | Blue-grey |

The measured resistivity for the test fluids #3 and #4 are similar to the control K-HIL fluid coating but with higher optical density (Table 6). Note that the optical for Exp #4, 3 passes, 20 mm/s is the same as the K-HIL control proprietary hole carrier layer, namely, 0.10, but the sheet resistance is 4 Kohms vs. the control at 4 Mohms/sq. Looking at the coatings, there are many more particles visible with the naked eye in the present experimental HILs.

TABLE 6
Optical density and resistivity of coatings
over bottom grid electrodes.

| | # Passes/blade | Optical | |
|---|---|---|---|
| Fluid | speed | Density | Resistivity |
| K-HIL | 3 at 10 mm/s | 0.10 | 4 Mohm/square |
| Exp #3 | 3 at 30 mm/s | 0.14 | 1 Mohm/square |
| Exp #3 | 2 at 30 mm/s | 0.13 | 1.5 Mohm/square |
| Exp #3 | 3 at 20 mm/s | 0.12 | 800 Kohm/square |
| Exp#4 | 3 at 30 mm/s | 0.11 | 450 Kohm/square |
| Exp#4 | 3 at 20 mm/s | 0.10 | 400 Kohm/square |
| Exp#4 | 3 at 40 mm/s | 0.16 | 100 Kohm/square |

### Example 5

### Preparation and Solubility of the Charge Transfer Complex of F4-TCNQ and TTEF-BBT

In this study a mole ratio of approximately 35% of F4-TCNQ on BBT-TTEF was required to generate conductive coatings of the charge transfer complex. In solution, only about 15 to 20 mol % of F4-TCNQ on BBT-TTEH was needed to completely quench the 660 nm absorbance of the copolymer. Initial solvent screening was carried out at the 35 mole % ratio. The charge transfer reaction is conveniently carried out in methylene chloride.

A stock solution of BBT-TTEF was made by dissolving 29.4 mg of BBT-TTEF (0.045 mmoles) in 4.4 grams of methylene chloride. By means of a polyethylene disposable pipet, 4.02 grams (containing 26.7 mg, 0.041 mmoles) of this stock solution was then transferred into a clean 3 dram clear glass vial equipped with a magnetic stirrer. With gentle stirring, the F4TCNQ (4.0 mg, 0.0145 mmoles, in 4.0 grams of methylene chloride) solution was added drop-wise. The solution color rapidly changed from blue to black. The resulting solution had a final concentration of 0.38 w/w % with no observable insoluble material and was stable for several weeks.

### Example 6

### Two-Stage Method with F4-TCNQ and TTEF-BBT

A two stage approach to making coatings of the CTC was made by coating and drying a solution of BBT-TTEF (17.0 mg in 1.5 g of toluene) onto ST-504 (heat-stabilized PET) with a #3 coating rod to result in a blue layer. A solution of F4-TCNQ (2.0 mg in 2.0 g of ethyl acetate) was then coated with a #3 coating rod on the surface of the blue BBT-TTEF layer. The blue color was bleached immediately and the wet coating was rinsed with excess ethyl acetate leaving a light gray coating. Properties and spectra of this two stage coating were similar to coatings that were made by direct coating of ODCB solutions of the CTC.

Although the solvents used in the current example will attack the underlying layers, this method of forming the F4-TCNQ/BBT-TTEF complex may eventually allow the use of solvents which are not capable of solvating the F4-TCNQ/BBT-TTEF complex but are still orthogonal (i.e. non-destructive) to the underlying layers.

### Example 7

### Two-Stage Method with F2-TCNQ and TTEF-BBT

As shown in Example 2, reaction of as much as 100 mole % of F2-TCNQ with TTEF-BBT in solution does not lead to a complete loss of the 670 nm absorbance of the copolymer. It was found, however, that complete loss of the TTEF-BBT absorbance at 670 nm occurs with 35 mole % of F2-TCNQ when a deep blue solution of the components was coated and dried to give a light gray conductive coating. The surface resistivity of the thin film was 1.5 MΩ/square and the thick film resistivity was 0.8 MΩ/square. Apparently, at the high concentration within the dry film, the mobile F2-TCNQ is immobilized and forced into complexation with the copolymer, whereas, in solution, F2-TCNQ remains partially dissociated from and in equilibrium with the copolymer.

### Example 8

### Reaction of NOPF₆ and BBT-TTEH

To a solution of BBT-TTEH in dichloromethane a solution of NOPF6 in acetonitrile was added in aliquots. The reaction was followed by UV/VIS spectroscopy.

At 20% equivalents of NOPF₆ (based on the number of equivalents of polymer repeat units) the absorption peak of the polymer is significantly reduced, but the polymer absorption peak does not completely disappear until 40% eq. have been added.

Coatings of the NOPF₆ and BBT-TTEH redox couple at 40% NOPF6 are completely colorless.

### Example 9

### Alternative Oxidizing Agents

Two oxidizing agents that have been used with BBT-TTC6 are nitrosonium hexafluorophosphate (NOPF6) and thianthrenium hexafluorophosphate. The latter is made from the reaction of thianthrene and nitrosonium hexafluorophosphate.

Schema 6, below illustrates the use of NOPF6 as an oxidizing agent with BBT-TTC6. In this titration the polymer is dissolved in dichloromethane; NOPF6 is dissolved in acetonitrile. The reaction products are the radical cation of the polymer coupled with PF6 anion and nitric oxide (NO). Nitric oxide and methylene chloride can be removed from the reaction mixture by bubbling nitrogen through the solution. Although the BBT-TTC6 itself is not soluble in acetonitrile, the reaction products are completely soluble. This is particularly advantageous because none of the active layer components of the PV cell are soluble in this solvent which means that the reaction products of redox couple can be coated on the active layer.

At 20% equivalents of NOPF6 (based on the number of equivalents of polymer repeat units) the absorption peak of the polymer is significantly reduced, but the polymer absorption peak does not completely disappear until 40% eq. have been added. Coatings of this redox couple at 40% NOPF6 are completely colorless.

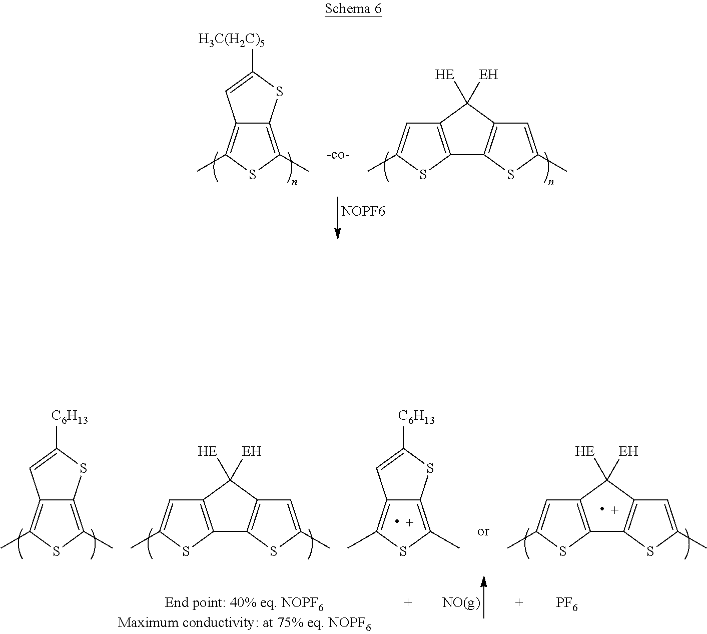

### Example 10

### Embodiments of an Organic Photovoltaic Device with the Hole Carrier Layer of the Present Invention

Functional photovoltaic devices were constructed using the hole carrier layer of the present invention. With reference to FIG. 1, the devices 100 included substrates 110 and 170, and silver grid electrodes 120 and 160. The photoactive layer 140 comprised poly(3-hexylthiophene) (P3HT) and a fullerene. A hole blocking layer 130 was interposed between a first side of the photoactive layer 140 and one electrode 120. A hole carrier layer 150 was between the opposite side of the photoactive layer 140 and electrode 160. Electrodes 120 and 160 were connected to an external load.

In certain embodiments, the hole carrier layer 150 comprised a BBT-TTC6 F4TCNQ redox couple. In other embodiments, the hole carrier layer 150 comprised a BBT-TTC6 F2TCNQ redox couple. When electrodes 120 and 160 were connected to an external load and the device was exposed to sunlight, the device produced electrical power.

1. An article comprising a first electrode, a second electrode, a photoactive layer between the first electrode and the second electrode, and a hole carrier layer between the first electrode and the photoactive layer, the hole carrier layer comprising an oxidizing agent and a hole carrier polymer, wherein the oxidizing agent is selected from the group consisting of 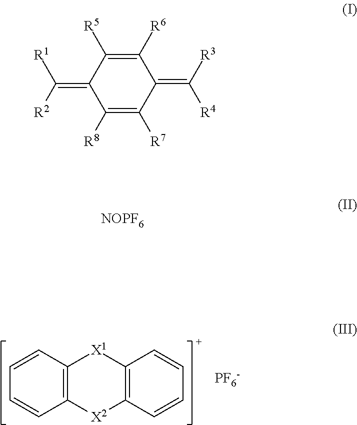
and blends thereof, wherein R¹ to R⁸ are independently of each other selected from the group consisting of hydrogen, fluorine, chlorine, bromine, iodine, NO₂, NH₂, COOH, and CN, with the provision that at least two of R¹ to R⁸ are different from hydrogen, and wherein X¹ and X² are independently of each other selected from the group consisting of O, S, Se, NR⁹ with R⁹ being selected from the group consisting of alkyl having from 1 to 10 carbon atoms, phenyl and phenyl substituted with alkyl having from 1 to 10 carbon atoms, or one of R⁵ to R⁸ may be -Sp-Pol selected from the group consisting of the following (I-Pol-A), (I-Pol-B), (I-Pol-C) 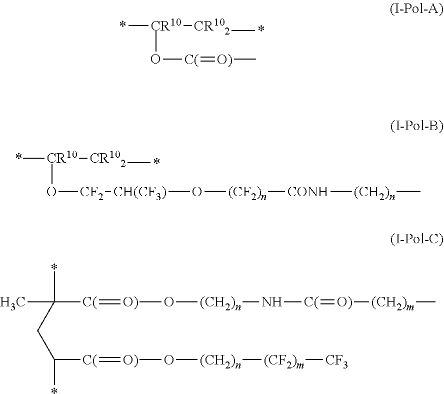
and blends thereof, with R¹⁰ being hydrogen or fluorine, preferably fluorine; each n and m being independently of the other a number between 0 and 10, preferably between 0 and 5, most preferably 1 or 2; and “*” indicating the bonds to other monomeric units of the polymer. In certain preferred embodiments, at least two of R⁵-R⁸ are selected from the group consisting of hydrogen, fluorine, chlorine, NO₂, COOH, and CN.

2. The article according to claim 1, wherein the hole carrier polymer is selected from the group consisting of polythiophenes, polyanilines, polycarbazoles, polyvinylcarbazoles, polyphenylenes, polyphenylvinylenes, polysilanes, polythienylenevinylenes, polyisothianaphthanenes, and copolymers or blends thereof.

3. The article according to claim 1, wherein the hole carrier polymer comprises one or more monomeric unit selected from the following 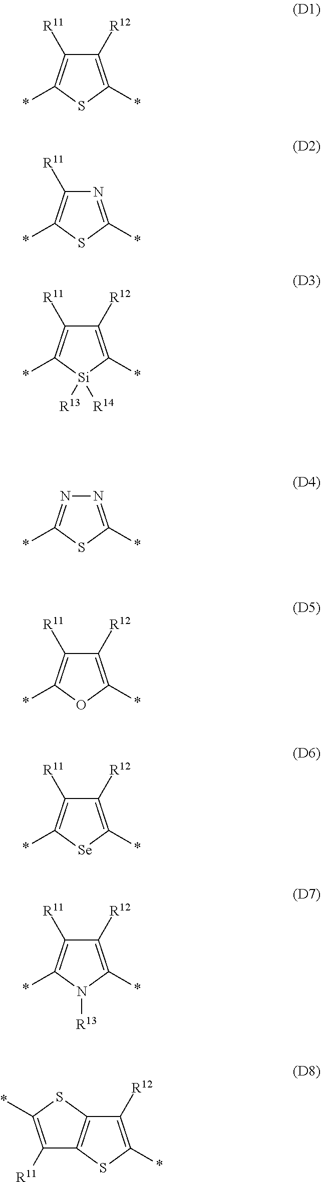 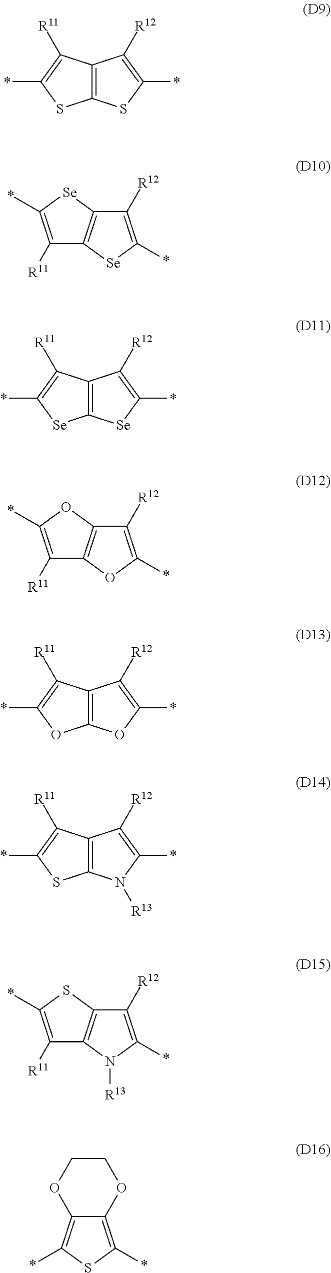 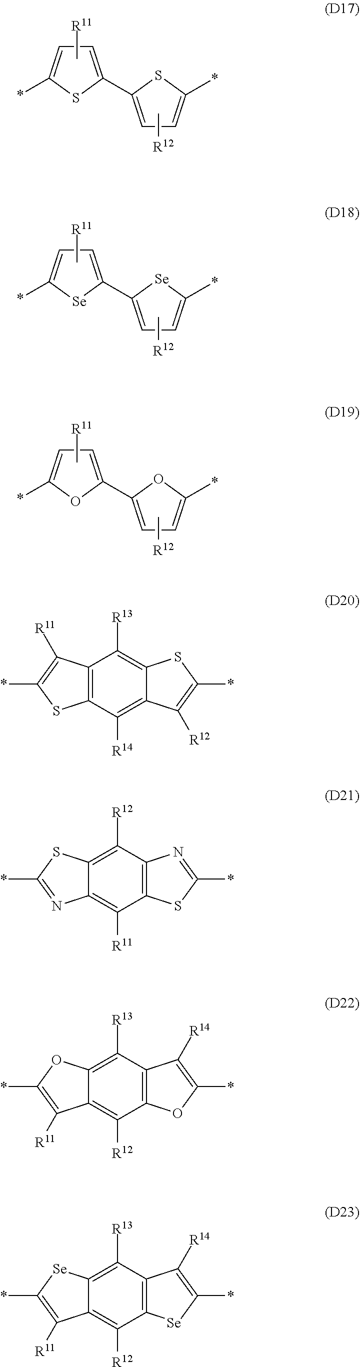 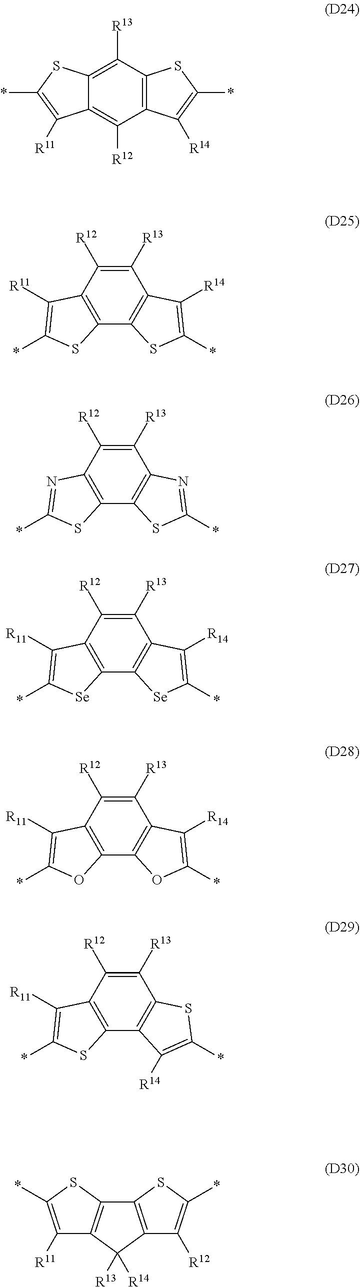 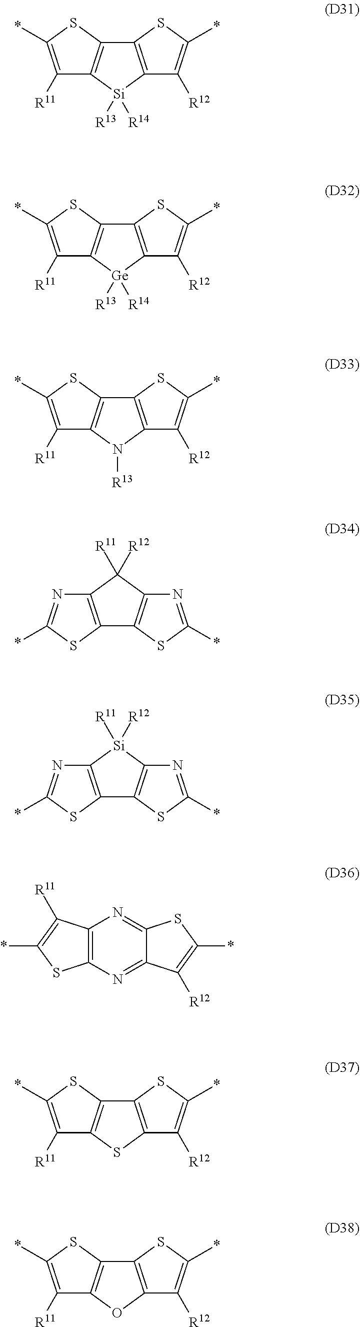 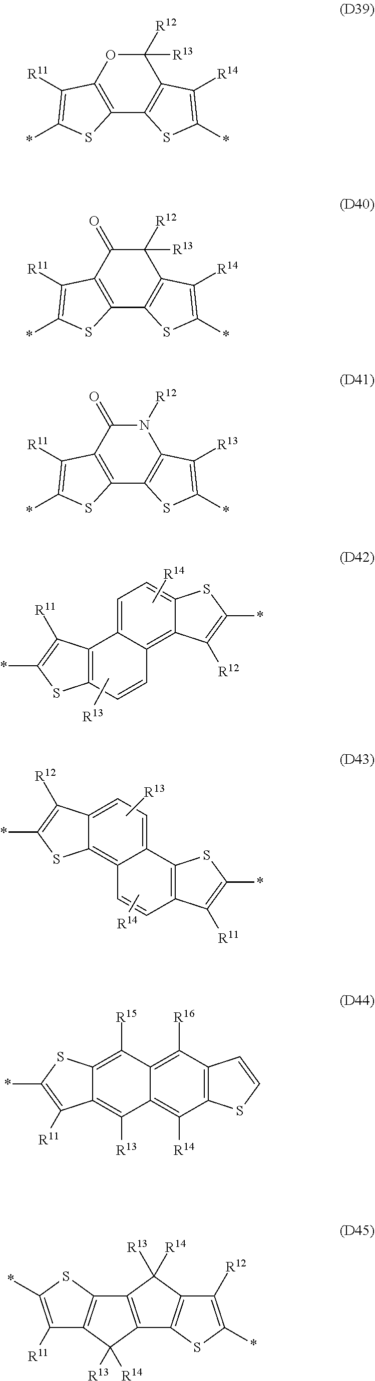 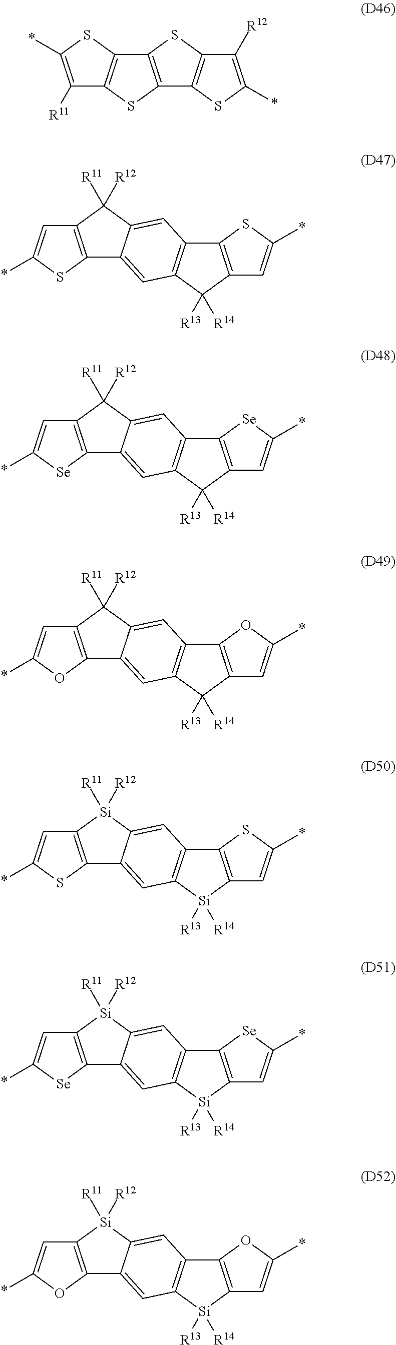 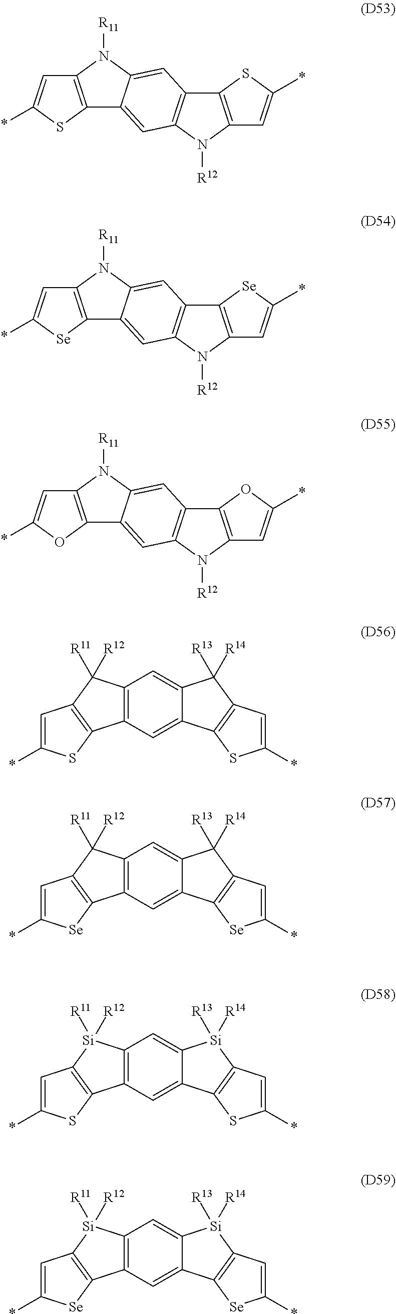 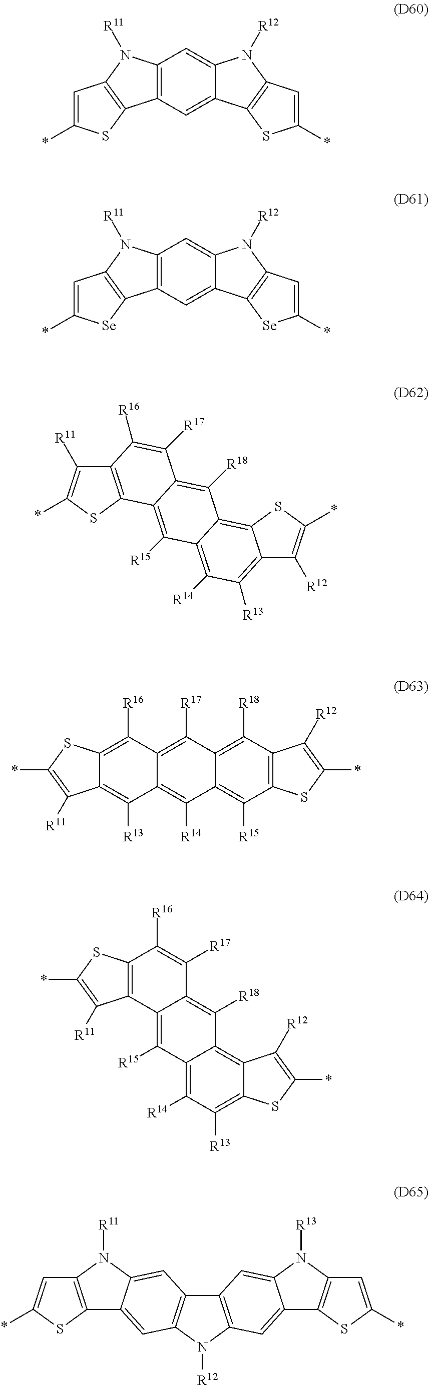 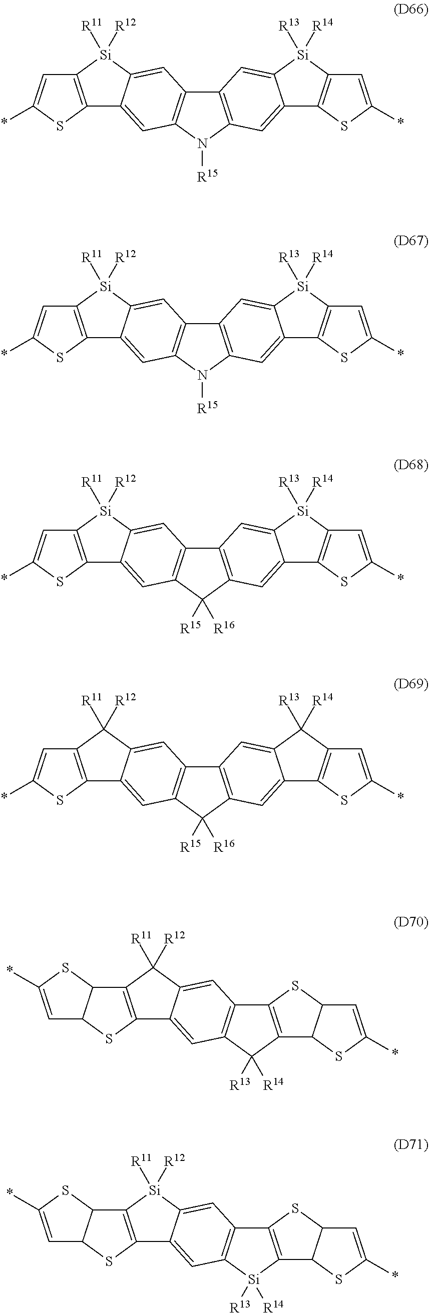 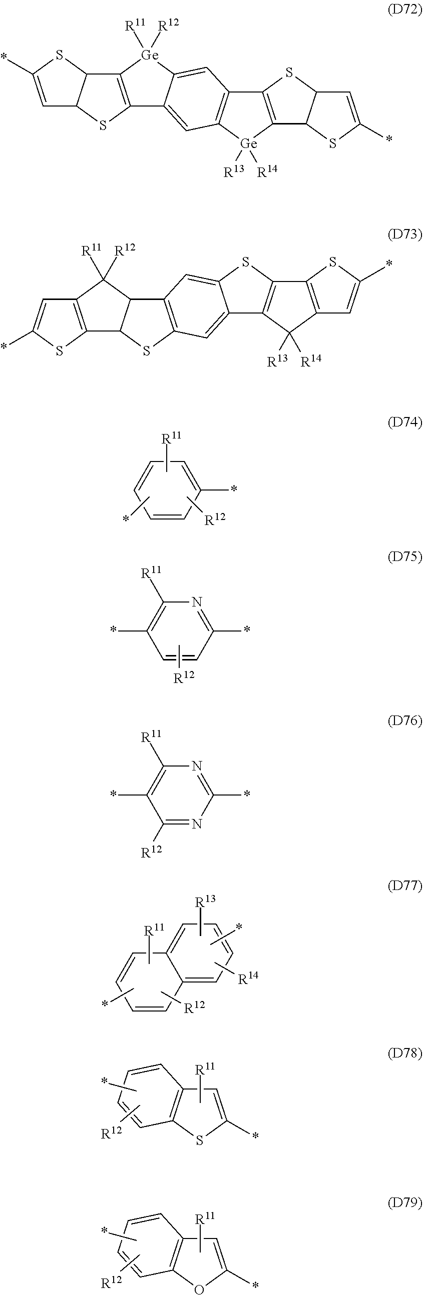 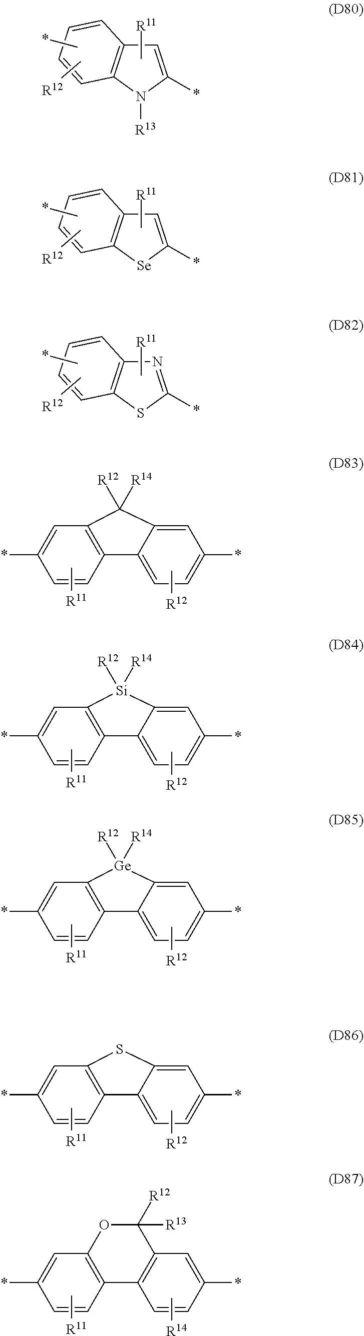 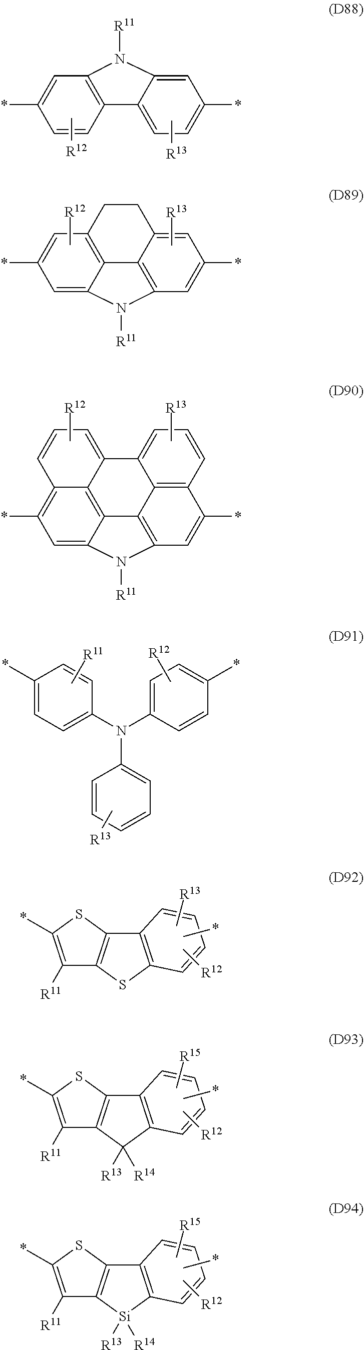 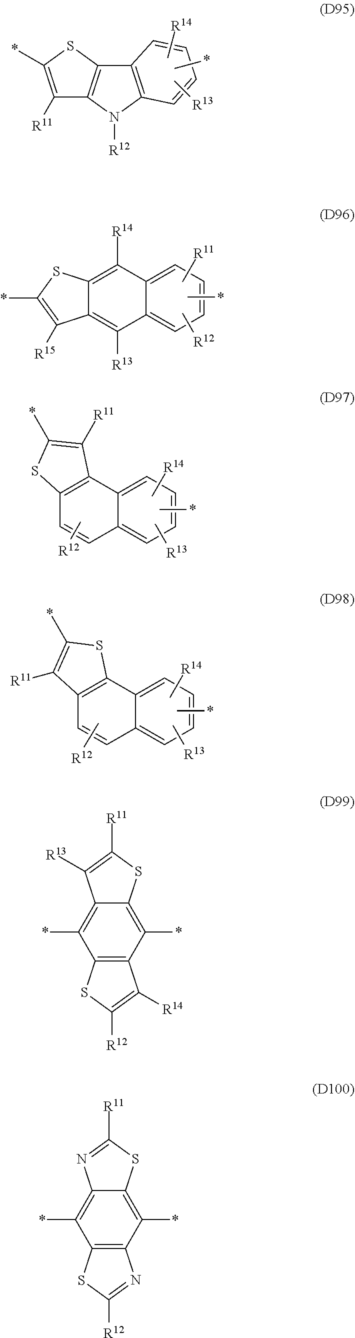 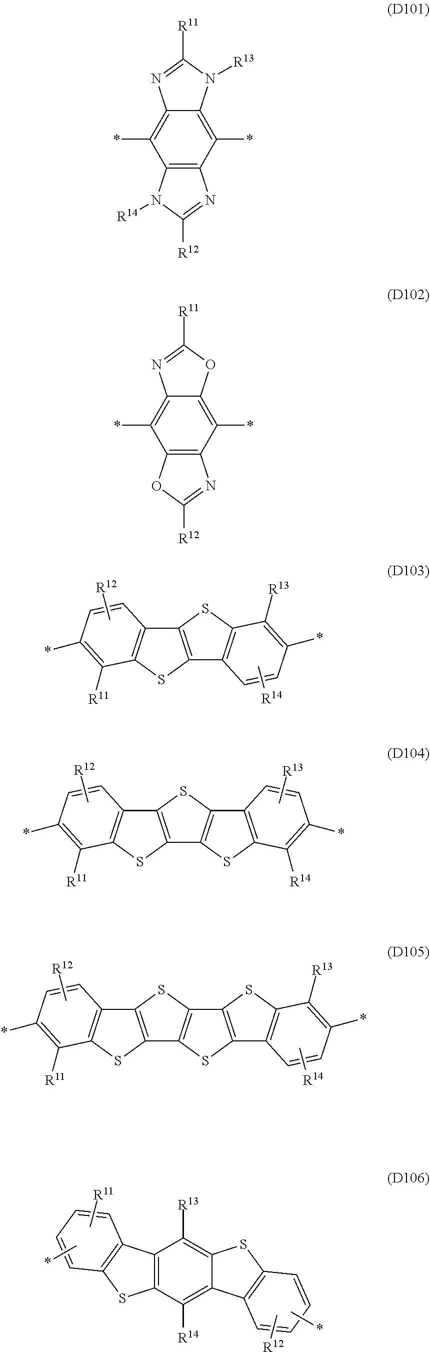 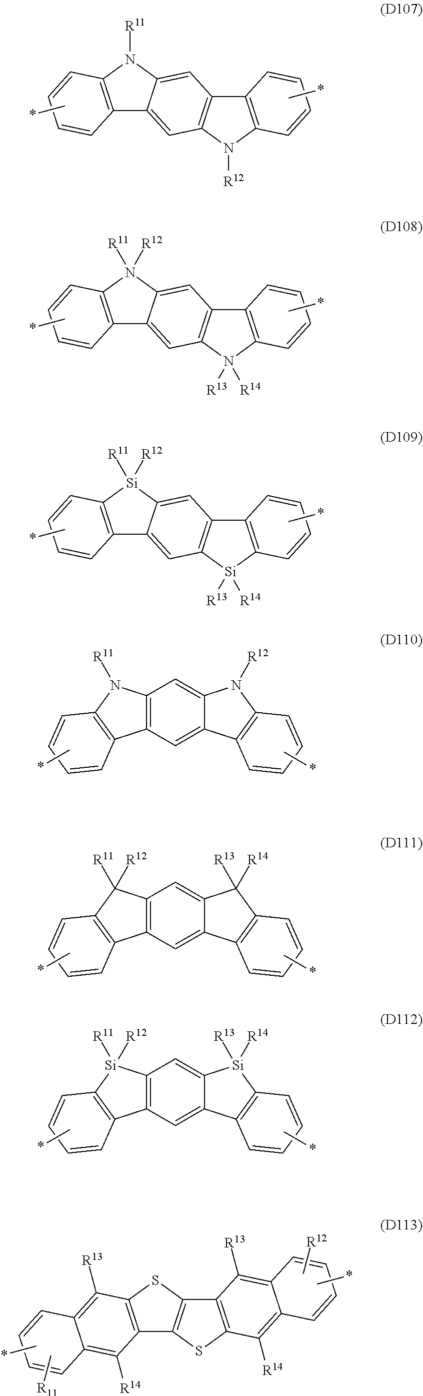 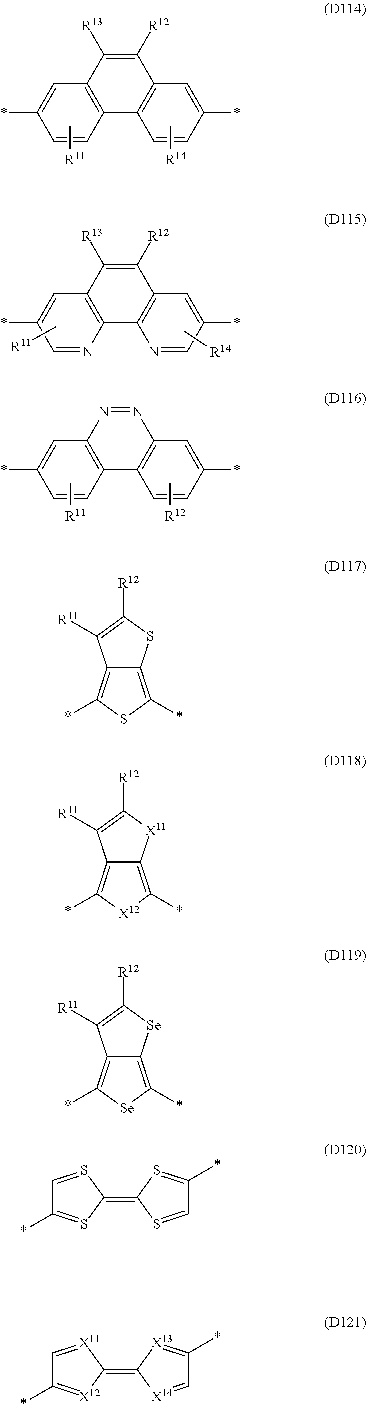 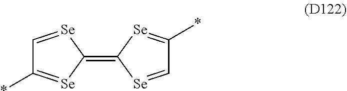
and their respective mirror images, wherein one of X¹¹ and X¹² is S and the other is Se, and one of X¹³ and X¹⁴ is S and the other is Se, and R¹¹, R¹², R¹³, R¹⁴, R¹⁵, R¹⁶, R¹⁷ and R¹⁸ are independently of each other selected from the group consisting of hydrogen, F, Br, Cl, —CN, —NC, —NCO, —NCS, —OCN, —SCN, —C(O)NR¹R², —C(O)X⁰, —C(O)R¹, —NH₂, —NR¹R², —SH, —SR¹, —SO₃H, —SO₂R¹, —OH, —NO₂, —CF₃, —SF₅, optionally substituted silyl or hydrocarbyl with 1 to 40 C atoms that is optionally substituted and optionally comprises one or more hetero atoms.

4. The article according to claim 1, wherein the hole carrier layer further comprises a binder.

5. The article according to claim 4, wherein the binder comprises a polymer.

6. The article according to claim 5, wherein the polymer comprises an acrylic resin, a ionic polymer, or a polymer comprising an electron accepting group.

7. The article according to claim 4, wherein the binder comprises a sol gel.

8. The article of claim 4, wherein the binder is at most 50% by volume of the hole carrier layer.

9. The article of claim 4, wherein the binder is at most 1% by volume of the hole carrier.

10. The article of claim 1, wherein the hole carrier layer has a thickness of at least 5 nm.

11. The article of claim 1, wherein the hole carrier layer has a thickness of at most 500 nm.

12. The article of any one or more of the preceding claims, wherein the photoactive layer comprises an electron donor material and an electron acceptor material.

13. The article of claim 12, wherein the electron donor material comprises a polymer selected from the group consisting of polythiophenes, polyanilines, polycarbazoles, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxalines, polybenzoisothiazoles, polybenzothiazoles, polythienothiophenes, poly(thienothiophene oxide)s, polydithienothiophenes, poly(dithienothiophene oxide)s, polyfluorenes, polytetrahydroisoindoles, and copolymers thereof.

14. The article of claim 12, wherein the electron donor material comprises a polythiophene or a polycyclopentadithiophene.

15. The article of claim 12, wherein the electron acceptor material comprises a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

16. The article of claim 12, wherein the electron acceptor material comprises a substituted fullerene.

17. The article of claim 12, wherein the electron donor material comprises a polymer having the repeat unit of formula IV, 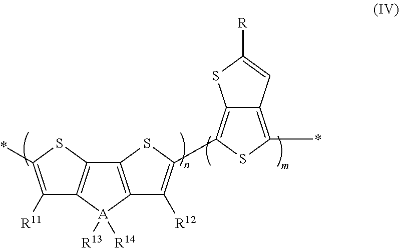
where R, R¹¹, R¹², R¹³, and R¹⁴ are independently of each other selected from the group consisting of hydrogen, or hydrocarbyl with 1 to 40 C atoms that is optionally substituted and optionally comprises one or more hetero atoms, and A is C or Si.

18. The article of claim 17, wherein R, R¹¹, R¹², R¹³, and R¹⁴ are independently of each other selected from the group consisting of hydrogen, substituted or unsubstituted C₁-C₂₄ alkyl, C₁-C₂₄ alkyl interrupted by one or more oxygen, aryl, C₁-C₂₄ alkyoxy, or aryloxy.

19. The method for manufacturing the article of claim 1, wherein the method comprises the steps of
(a) mixing the hole carrier polymer and the oxidizing agent and dissolving them together in a solvent, or dissolving the hole carrier polymer in a first solvent and the oxidizing agent in a second solvent and then mixing the two solutions; and
(b) subsequently coating the resulting solution from step (a) over a layer underneath,
wherein the first and second solvent may be the same or different, and wherein the article is a photovoltaic cell.

20. The method for manufacturing the article of claim 1, wherein the method comprises the steps of
(a) dissolving the hole carrier polymer in a first solvent to obtain a first solution;
(b) coating the first solution over a layer underneath;
(c) drying the resulting layer of hole carrier polymer;
(d) dissolving the oxidizing agent in a second solvent to obtain a second solution; and
(c) coating the second solution over the layer of hole carrier polymer obtained in step (c);
wherein the first and second solvent may be the same or different, and wherein the article is a photovoltaic cell.

21. The method according to claim 19 or claim 20, wherein the solvent, the first solvent and the second solvent are independently of each other selected from organic solvents.

22. The method according to claim 21, wherein the solvent, the first solvent and the second solvent are independently of each other selected from the group consisting of aliphatic hydrocarbons, chlorinated hydrocarbons, aromatic hydrocarbons, ketones, ethers and mixtures thereof. Additional solvents which can be used include 1,2,4-trimethylbenzene, 1,2,3,4-tetra-methyl benzene, pentylbenzene, mesitylene, cumene, cymene, cyclohexylbenzene, diethylbenzene, tetralin, decalin, 2,6-lutidine, 2-fluoro-m-xylene, 3-fluoro-o-xylene, 2-chlorobenzotrifluoride, N,N-dimethylformamide, 2-chloro-6-fluorotoluene, 2-fluoroanisole, anisole, 2,3-dimethylpyrazine, 4-fluoroanisole, 3-fluoroanisole, 3-trifluoro-methylanisole, 2-methylanisole, phenetol, 4-methylanisole, 3-methylanisole, 4-fluoro-3-methylanisole, 2-fluorobenzonitrile, 4-fluoroveratrol, 2,6-dimethylanisole, 3-fluorobenzo-nitrile, 2,5-dimethylanisole, 2,4-dimethylanisole, benzonitrile, 3,5-dimethylanisole, N,N-dimethylaniline, ethyl benzoate, 1-fluoro-3,5-dimethoxybenzene, 1-methylnaphthalene, N-methylpyrrolidinone, 3-fluorobenzotrifluoride, benzotrifluoride, dioxane, trifluoromethoxy-benzene, 4-fluorobenzotrifluoride, 3-fluoropyridine, toluene, 2-fluoro-toluene, 2-fluorobenzotrifluoride, 3-fluorotoluene, 4-isopropylbiphenyl, phenyl ether, pyridine, 4-fluorotoluene, 2,5-difluorotoluene, 1-chloro-2,4-difluorobenzene, 2-fluoropyridine, 3-chlorofluoro-benzene, 1-chloro-2,5-difluorobenzene, 4-chlorofluorobenzene, chloro-benzene, o-dichlorobenzene, 2-chlorofluorobenzene, p-xylene, m-xylene, o-xylene or mixture of o-, m-, and p-isomers.

23. The method according to claim 21, wherein the solvent, the first solvent and the second solvent are independently of each other selected from the group consisting of methylene chloride (CH₂Cl₂), ortho-dichlorobenzene, meta-dichlorobenzene, para-dichlorobenzene and a blend of methylene chloride and n-propanol in a volume ratio of 2:1.
